(19) United States
(12) Patent Application Publication
(10) Pub. No.: US 2026/0052869 A1
(43) Pub. Date: Feb. 19, 2026

(54) ARRAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Cuicui Liang, Beijing (CN); Shuo Li, Beijing (CN); Yamei Gao, Beijing (CN); Chao Yang, Beijing (CN); Bin Wang, Beijing (CN); Haijun Qiu, Beijing (CN); Weifeng Zhou, Beijing (CN); Jiandong Bao, Beijing (CN); Ling Shi, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/690,437

(22) PCT Filed: Jun. 21, 2023
(86) PCT No.: PCT/CN2023/101766

§ 371 Date: Mar. 8, 2024

(51) Int. Cl. H10K 59/131; H10K 59/122; H10K 59/80

(52) U.S. Cl. CPC H10K 59/1315; H10K 59/122; H10K 59/80515

(57) ABSTRACT

An array substrate includes a base substrate; a signal line layer closest to an anode on the base substrate; an anode layer on a side of the signal line layer closest to the anode away from the base substrate; a pixel definition layer; and a plurality of subpixel apertures extending through the pixel definition layer. The anode layer includes a plurality of anodes. The signal line layer closest to the anode comprises a plurality of signal lines. An orthographic projection of a portion of a respective anode in a respective subpixel aperture on the base substrate at least partially overlaps with an orthographic projection of the signal line layer closest to the anode on the base substrate, forming one or more overlapping areas. The one or more overlapping areas have a substantial mirror symmetry with respect to a plane perpendicular to the respective anode and intersecting the respective anode.

### TECHNICAL FIELD

The present invention relates to display technology, more particularly, to an array substrate and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, comprising a base substrate; a signal line layer closest to an anode on the base substrate; an anode layer on a side of the signal line layer closest to the anode away from the base substrate; a pixel definition layer; and a plurality of subpixel apertures extending through the pixel definition layer; wherein the anode layer comprises a plurality of anodes; the signal line layer closest to the anode comprises a plurality of signal lines; an orthographic projection of a portion of a respective anode of the plurality of anodes in a respective subpixel aperture of the plurality of subpixel apertures on the base substrate at least partially overlaps with an orthographic projection of the signal line layer closest to the anode on the base substrate, forming one or more overlapping areas; and the one or more overlapping areas have a substantial mirror symmetry with respect to a plane perpendicular to the respective anode and intersecting the respective anode.

Optionally, the signal line layer closest to the anode comprises a plurality of planarization enhancing blocks; and an orthographic projection of a respective planarization enhancing block of the plurality of planarization enhancing blocks on the base substrate substantially covers an orthographic projection of at least a main anode part of a respective anode of the plurality of anodes on the base substrate.

Optionally, the orthographic projection of the main anode part on the base substrate substantially overlaps with an orthographic projection of a central region of the respective planarization enhancing block on the base substrate; and an orthographic projection of a peripheral region of the respective planarization enhancing block on the base substrate surrounds the orthographic projection of the main anode part on the base substrate.

Optionally, the plurality of planarization enhancing blocks are parts of a unitary structure.

Optionally, an orthographic projection of at least a main anode part of a respective anode of the plurality of anodes on the base substrate is at least partially surrounded by an orthographic projection of portions of the signal line layer closest to the anode on the base substrate in a substantially symmetrical manner.

Optionally, the anode layer comprises a first respective anode; the signal line layer closest to the anode comprises multiple signal lines; an orthographic projection of the first respective anode on the base substrate at least partially overlaps with each of orthographic projections of the multiple signal lines on the base substrate; and the multiple signal lines are substantially evenly distributed along a first direction with respect to a first main anode part of the first respective anode.

Optionally, portions of the multiple signal lines, in a region crossing over the first respective anode, have a substantial mirror symmetry with respect to a plane perpendicular to the first respective anode, intersecting the first respective anode, and substantially parallel to a second direction.

Optionally, the multiple signal lines comprise a first signal line, a second signal line, and a third signal line; the first signal line and the third signal line are two adjacent data lines of a plurality of data lines configured to provide data signals to two adjacent columns of subpixels, respectively; and the second signal line is a low voltage signal line configured to provide a low voltage signal to a cathode of a light emitting element.

Optionally, the anode layer comprises a third respective anode; the signal line layer closest to the anode comprises a fourth signal line; an orthographic projection of the third respective anode on the base substrate at least partially overlaps with an orthographic projection of the fourth signal line on the base substrate; and a portion of the fourth signal line, in a region crossing over the third respective anode, have a substantial mirror symmetry with respect to a plane perpendicular to the third respective anode, intersecting the third respective anode, and substantially parallel to a second direction.

Optionally, the fourth signal line is a voltage supply line configured to provide a voltage supply signal to a pixel driving circuit.

Optionally, the anode layer comprises a plurality of anodes; the signal line layer closest to the anode comprises a signal line; an orthographic projection of a respective anode of the plurality of anodes on the base substrate at least partially overlaps with an orthographic projection of the signal line on the base substrate; a portion of the signal line, in a region crossing over the respective anode, have a substantial mirror symmetry with respect to a plane perpendicular to the respective anode, intersecting the respective anode, and substantially parallel to a second direction; the signal line layer closest to the anode further comprises a first portion and a second portion; an orthographic projection of the first portion on the base substrate is on a first side of the orthographic projection of at least a main anode part of an individual anode on the base substrate; an orthographic projection of a second portion on the base substrate is on a second side of the orthographic projection of at least the main anode part of the individual anode on the base substrate, the first side being opposite to the second side; and the orthographic projection of the first portion on the base substrate and the orthographic projection of the second portion on the base substrate have a substantial mirror symmetry with respect to a plane perpendicular to the individual anode, intersecting the individual anode, and substantially parallel to the second direction.

Optionally, the anode layer comprises a plurality of anodes; the signal line layer closest to the anode comprises a first signal line, a second signal line, a third signal line, and a fourth signal line; an orthographic projection of at least a main anode part of a respective anode of the plurality of anodes on the base substrate at least partially overlaps with an orthographic projection of the first signal line on the base substrate, at least partially overlaps with an orthographic projection of the second signal line on the base substrate, at least partially overlaps with an orthographic projection of the third signal line on the base substrate, and at least partially overlaps with an orthographic projection of the fourth signal line on the base substrate; the first signal line is on a first side of a central point of the main anode part of the respective anode, the second signal line is on a second side of the central point of the main anode part of the respective anode, the third signal line is on a third side of the central point of the main anode part of the respective anode, and the fourth signal line is on a fourth side of the central point of the main anode part of the respective anode; the first side and the second side are opposite to each other; the third side and the fourth side are opposite to each other; the orthographic projection of the first signal line on the base substrate and the orthographic projection of the second signal line on the base substrate have a substantial mirror symmetry with respect to a plane intersecting the central point of the main anode part of the respective anode, perpendicular to the main anode part of the respective anode, and substantially parallel to a second direction; and the orthographic projection of the third signal line on the base substrate and the orthographic projection of the fourth signal line on the base substrate have a substantial mirror symmetry with respect to a plane intersecting the central point of the main anode part of the respective anode, perpendicular to the main anode part of the respective anode, and substantially parallel to a first direction.

Optionally, the first signal line, the second signal line, the third signal line, and the fourth signal line are signal lines in an interconnected voltage supply network in the signal line layer closest to the anode.

Optionally, the interconnected voltage supply network in the third signal line layer has a substantial mirror symmetry with respect to a plane perpendicular to an individual anode, intersecting the individual anode, and substantially parallel to the second direction; wherein the array substrate further comprises an encapsulating layer on a side of the third signal line layer away from the base substrate; and a black matric and a color filter on a side of the encapsulating layer away from the third signal line layer.

Optionally, the signal line layer closest to the anode comprises a plurality of planarization enhancing blocks; and an orthographic projection of a respective planarization enhancing block of the plurality of planarization enhancing blocks on the base substrate substantially covers an orthographic projection of a respective subpixel aperture of the plurality of subpixel apertures on the base substrate.

Optionally, an orthographic projection of the respective planarization enhancing block on the base substrate substantially covers an orthographic projection of at least a main anode part of the respective anode on the base substrate.

Optionally, the anode layer comprises a first respective anode; the plurality of planarization enhancing blocks comprise a first planarization enhancing block; the plurality of subpixel apertures comprise a first subpixel aperture; a first main anode part of the first respective anode is in contact with organic materials through the first subpixel aperture; an orthographic projection of the first planarization enhancing block on the base substrate completely covers an orthographic projection of the first subpixel aperture on the base substrate, and partially overlaps with an orthographic projection of a first main anode part of the first respective anode on the base substrate; the first main anode part comprises a first edge portion on a first side of the first subpixel aperture, a second edge portion on a second side of the first subpixel aperture, a third edge portion on a third side of the first subpixel aperture, and a fourth edge portion on a fourth side of the first subpixel aperture; the first side and the second side are opposite to each other; the third side and the fourth side are opposite to each other; the orthographic projection of the first planarization enhancing block on the base substrate is non-overlapping with an orthographic projection of the first edge portion on the base substrate, is non-overlapping with an orthographic projection of the second edge portion on the base substrate, is non-overlapping with an orthographic projection of the third edge portion on the base substrate, and is non-overlapping with an orthographic projection of the fourth edge portion on the base substrate; the first edge portion and the second edge portion have a substantial mirror symmetry with respect to a plane perpendicular to the first main anode part, intersecting the first main anode part, and substantially parallel to a second direction; and the third edge portion and the fourth edge portion have a substantial mirror symmetry with respect to a plane perpendicular to the first main anode part, intersecting the first main anode part, and substantially parallel to a first direction.

Optionally, the anode layer further comprises a second respective anode and a third respective anode; the plurality of planarization enhancing blocks further comprise a second planarization enhancing block and a third planarization enhancing block; the plurality of subpixel apertures further comprise a second subpixel aperture and a third subpixel aperture; a second main anode part of the second respective anode is in contact with organic materials through the second subpixel aperture; an orthographic projection of the second planarization enhancing block on the base substrate completely covers an orthographic projection of the second subpixel aperture on the base substrate, and completely covers an orthographic projection of the second main anode part on the base substrate; a third main anode part of the third respective anode is in contact with organic materials through the third subpixel aperture; an orthographic projection of the third planarization enhancing block on the base substrate completely covers an orthographic projection of the third subpixel aperture on the base substrate, and partially overlaps with an orthographic projection of the third main anode part on the base substrate; the third main anode part comprises a corner portion on a first side of the third subpixel aperture and a main portion connected to the corner portion; the orthographic projection of the third planarization enhancing block on the base substrate is non-overlapping with an orthographic projection of the corner portion on the base substrate, and completely covers an orthographic projection of the main portion on the base substrate; the corner portion has a substantial mirror symmetry with respect to a plane perpendicular to the third main anode part, intersecting the third main anode part, and substantially parallel to a second direction; and the main portion has a substantial mirror symmetry with respect to a plane perpendicular to the third main anode part, intersecting the third main anode part, and substantially parallel to the second direction.

In another aspect, the present disclosure provides a display apparatus, comprising the array substrate describe herein or fabricated by a method described herein, and one or more integrated circuits connected to the array substrate.

In another aspect, the present disclosure provides an array substrate, comprising a base substrate; a first signal line layer on the base substrate; a first planarization layer on a side of the first signal line layer away from the base substrate; a second signal line layer on a side of the first planarization layer away from the first signal line layer; a second planarization layer on a side of the second signal line layer away from the first planarization layer; a third signal line layer on a side of the second planarization layer away from the second signal line layer; an anode layer on a side of the third signal line layer away from the base substrate; a pixel definition layer; and a plurality of subpixel apertures extending through the pixel definition layer; wherein the third signal line layer is a signal line layer closest to the anode layer; and wherein the anode layer comprises a plurality of anodes; the second signal line layer comprises a plurality of a first voltage supply line extends along a first direction; the third signal line layer comprises a plurality of a first voltage supply line extends along a second direction; the third signal line layer comprises a plurality of signal lines; an orthographic projection of a portion of a respective anode of the plurality of anodes in a respective subpixel aperture of the plurality of subpixel apertures on the base substrate at least partially overlaps with an orthographic projection of the signal line layer closest to the anode on the base substrate, forming one or more overlapping areas; and the one or more overlapping areas have a substantial mirror symmetry with respect to a plane perpendicular to the respective anode and intersecting the respective anode.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2A is a circuit diagram illustrating the structure of a pixel driving circuit in some embodiments according to the present disclosure.

FIG. 2B is a timing diagram illustrating the operation of a pixel driving circuit in some embodiments according to the present disclosure.

FIG. 3A is a diagram illustrating the structure of an array substrate in some embodiments according to the present disclosure.

FIG. 3B is a schematic diagram illustrating an arrangement of pixel driving circuits in the array substrate depicted in FIG. 3A.

FIG. 3C is a diagram illustrating the structure of a light shielding layer in the array substrate depicted in FIG. 3A.

FIG. 3D is a diagram illustrating the structure of a first semiconductor material layer in the array substrate depicted in FIG. 3A.

FIG. 3E is a diagram illustrating the structure of a first gate metal layer in the array substrate depicted in FIG. 3A.

FIG. 3F is a diagram illustrating the structure of a second gate metal layer in the array substrate depicted in FIG. 3A.

FIG. 3G is a diagram illustrating vias extending through a first inter-layer dielectric layer in the array substrate depicted in FIG. 3A.

FIG. 3H is a diagram illustrating the structure of a second semiconductor material layer in the array substrate depicted in FIG. 3A.

FIG. 3I is a diagram illustrating vias extending through a second inter-layer dielectric layer in the array substrate depicted in FIG. 3A.

FIG. 3J is a diagram illustrating the structure of a third gate metal layer in the array substrate depicted in FIG. 3A.

FIG. 3K is a diagram illustrating vias extending through a passivation layer in the array substrate depicted in FIG. 3A.

FIG. 3L is a diagram illustrating the structure of a first signal line layer in the array substrate depicted in FIG. 3A.

FIG. 3M is a diagram illustrating vias extending through a first planarization layer in the array substrate depicted in FIG. 3A.

FIG. 3N is a diagram illustrating the structure of a second signal line layer in the array substrate depicted in FIG. 3A.

FIG. 3O is a diagram illustrating vias extending through a second planarization layer in the array substrate depicted in FIG. 3A.

FIG. 3P is a diagram illustrating the structure of a third signal line layer in the array substrate depicted in FIG. 3A.

FIG. 3Q is a diagram illustrating vias extending through a third planarization layer in the array substrate depicted in FIG. 3A.

FIG. 3R is a diagram illustrating an anode layer in the array substrate depicted in FIG. 3A.

FIG. 4 is a cross-sectional view along an A-A′ line in FIG. 3A.

FIG. 5 is a schematic diagram illustrating the structure of an array substrate in some embodiments according to the present disclosure.

FIG. 6 illustrates light reflection by an anode in a related array substrate.

FIG. 7 illustrates occurrence of color separation in a related array substrate.

FIG. 8 illustrates a relative layout between an anode layer and a signal line layer closest to the anode in an array substrate in some embodiments according to the present disclosure.

FIG. 9 illustrates a relative layout between an anode layer and a signal line layer closest to the anode in an array substrate in some embodiments according to the present disclosure.

FIG. 10 illustrates a relative layout between an anode layer and a signal line layer closest to the anode in an army substrate in some embodiments according to the present disclosure.

FIG. 11A illustrates the structures of a second signal line layer, a third signal line layer, and an anode layer in an array substrate in some embodiments according to the present disclosure.

FIG. 11B illustrates the structure of a second signal line layer in an array substrate in some embodiments according to the present disclosure.

FIG. 11C illustrates the structure of a third signal line layer in an array substrate in some embodiments according to the present disclosure.

FIG. 11D illustrates the structure of an anode layer in an array substrate in some embodiments according to the present disclosure.

FIG. 11E illustrates the structures of a third signal line layer and an anode layer in an array substrate in some embodiments according to the present disclosure.

FIG. 12 illustrates a relative layout between an anode layer and a signal line layer closest to the anode in an array substrate in some embodiments according to the present disclosure.

FIG. 13 illustrates a relative layout between an anode layer and a signal line layer closest to the anode in an array substrate in some embodiments according to the present disclosure.

FIG. 14A is a diagram illustrating the structure of an array substrate in some embodiments according to the present disclosure.

FIG. 14B is a diagram illustrating the structure of a light shielding layer in the array substrate depicted in FIG. 14A.

FIG. 14C is a diagram illustrating the structure of a first semiconductor material layer in the array substrate depicted in FIG. 14A.

FIG. 14D is a diagram illustrating the structure of a first gate metal layer in the array substrate depicted in FIG. 14A.

FIG. 14E is a diagram illustrating the structure of a second gate metal layer in the array substrate depicted in FIG. 14A.

FIG. 14F is a diagram illustrating vias extending through an insulating layer in the array substrate depicted in FIG. 14A.

FIG. 14G is a diagram illustrating the structure of a first signal line layer in the array substrate depicted in FIG. 14A.

FIG. 14H is a diagram illustrating vias extending through a first planarization layer in the array substrate depicted in FIG. 14A.

FIG. 14I is a diagram illustrating the structure of a second signal line layer in the array substrate depicted in FIG. 14A.

FIG. 14J is a diagram illustrating the structure of a third signal line layer in the array substrate depicted in FIG. 14A.

FIG. 14K is a diagram illustrating the structure of an anode layer in the array substrate depicted in FIG. 14A.

FIG. 14L is a diagram illustrating the structure of a pixel definition layer in the array substrate depicted in FIG. 14A.

FIG. 15 is a diagram illustrating the structures of a third signal line layer and an anode layer in the array substrate depicted in FIG. 14A.

FIG. 16A is a diagram illustrating the structure of a first semiconductor material layer in an array substrate in some embodiments according to the present disclosure.

FIG. 16B is a diagram illustrating the structures of a first semiconductor material layer and a first gate metal layer in an array substrate in some embodiments according to the present disclosure.

FIG. 16C is a diagram illustrating the structures of a first semiconductor material layer, a first gate metal layer, and a second gate metal layer in an array substrate in some embodiments according to the present disclosure.

FIG. 16D is a diagram illustrating the structures of a first semiconductor material layer, a first gate metal layer, a second gate metal layer, a second semiconductor material layer, and a third gate metal layer in an array substrate in some embodiments according to the present disclosure.

FIG. 16E is a diagram illustrating the structures of a first semiconductor material layer, a first gate metal layer, a second gate metal layer, a second semiconductor material layer, a third gate metal layer, an inter-layer dielectric layer, and a first signal line layer in an array substrate in some embodiments according to the present disclosure.

FIG. 16F is a diagram illustrating the structures of a first semiconductor material layer, a first gate metal layer, a second gate metal layer, a second semiconductor material layer, a third gate metal layer, an inter-layer dielectric layer, a first signal line layer, a passivation layer, a first planarization layer, and a second signal line layer in an array substrate in some embodiments according to the present disclosure.

FIG. 16G is a diagram illustrating the structures of a first semiconductor material layer, a first gate metal layer, a second gate metal layer, a second semiconductor material layer, a third gate metal layer, an inter-layer dielectric layer, a first signal line layer, a passivation layer, a first planarization layer, a second signal line layer, a second planarization layer, and a third signal line layer in an array substrate in some embodiments according to the present disclosure.

FIG. 16H is a diagram illustrating the structures of a first semiconductor material layer, a first gate metal layer, a second gate metal layer, a second semiconductor material layer, a third gate metal layer, an inter-layer dielectric layer, a first signal line layer, a passivation layer, a first planarization layer, a second signal line layer, a second planarization layer, a third signal line layer, a third planarization layer, an anode layer, and a pixel definition layer in an array substrate in some embodiments according to the present disclosure.

FIG. 16I is a diagram illustrating the structure of a third signal line layer in an array substrate in some embodiments according to the present disclosure.

FIG. 16J is a diagram illustrating the structure of an anode layer in an array substrate in some embodiments according to the present disclosure.

FIG. 16K is a diagram illustrating the structure of a pixel definition layer in an array substrate in some embodiments according to the present disclosure.

FIG. 16L is a diagram illustrating the structures of a third planarization layer and an anode layer in an array substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

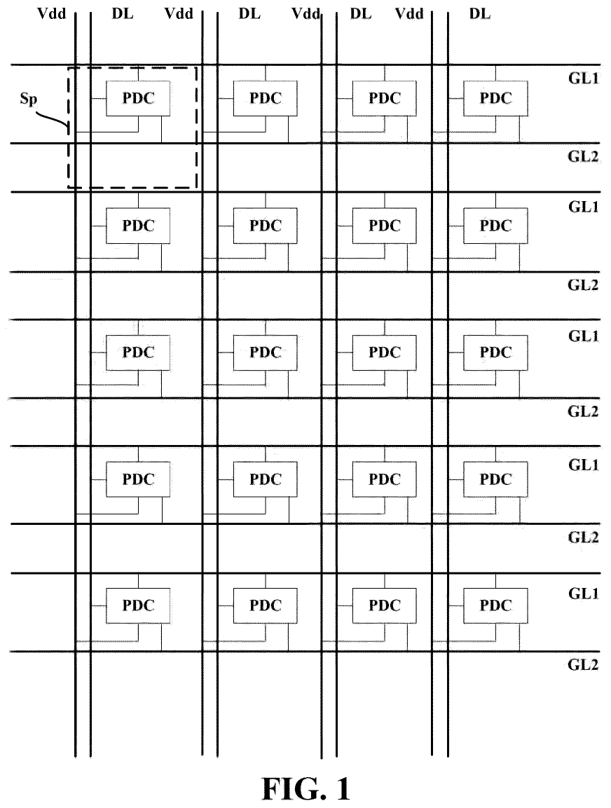

FIG. 1 is a plan view of an army substrate in some embodiments according to the present disclosure. Referring to FIG. 1, the array substrate includes an array of subpixels Sp. Each subpixel includes an electronic component, e.g., a light emitting element. In one example, the light emitting element is driven by a respective pixel driving circuit PDC. The array substrate includes a plurality of first gate lines GL1, a plurality of second gate lines GL2, a plurality of data lines DL, a plurality of voltage supply line Vdd, and a respective second voltage supply line (e.g., a low voltage supply line). Light emission in a respective subpixel Sp is driven by a respective pixel driving circuit PDC. In one example, a high voltage signal (e.g., a VDD signal) is input, through the respective high voltage supply line of the plurality of voltage supply line Vdd, to the respective pixel driving circuit PDC connected to an anode of the light emitting element; a low voltage signal (e.g., a VSS signal) is input, through a low voltage supply line, to a cathode of the light emitting element. A voltage difference between the high voltage signal (e.g., the VDD signal) and the low voltage signal (e.g., the VSS signal) is a driving voltage ΔV that drives light emission in the light emitting element.

Various appropriate pixel driving circuits may be used in the present array substrate. Examples of appropriate driving circuits include 3T1C, 2T1C, 4T1C, 4T2C, ST2C, 6T1C, 7T1C, 7T2C, 8T1C, and 8T2C. In some embodiments, the respective one of the plurality of pixel driving circuits is an 8T1C driving circuit. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

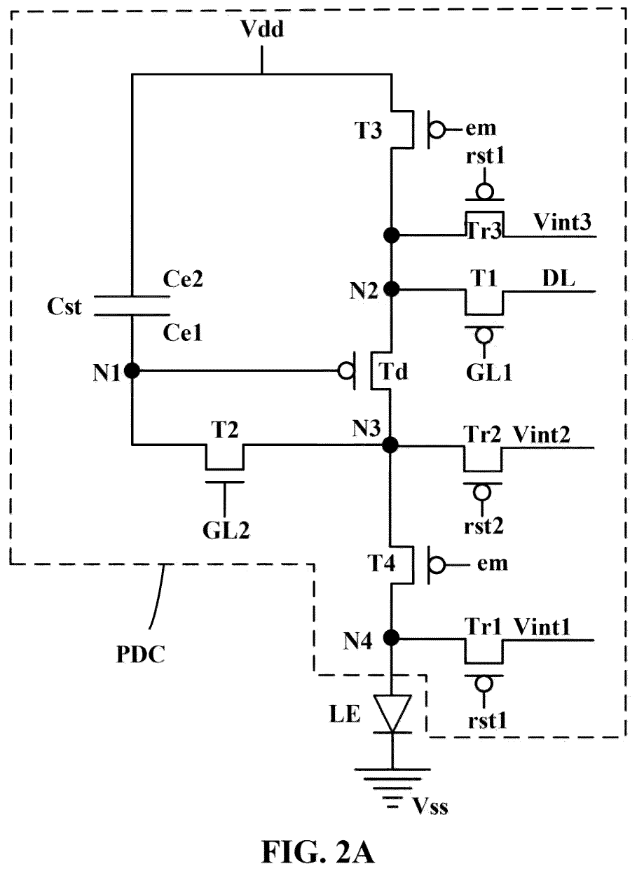

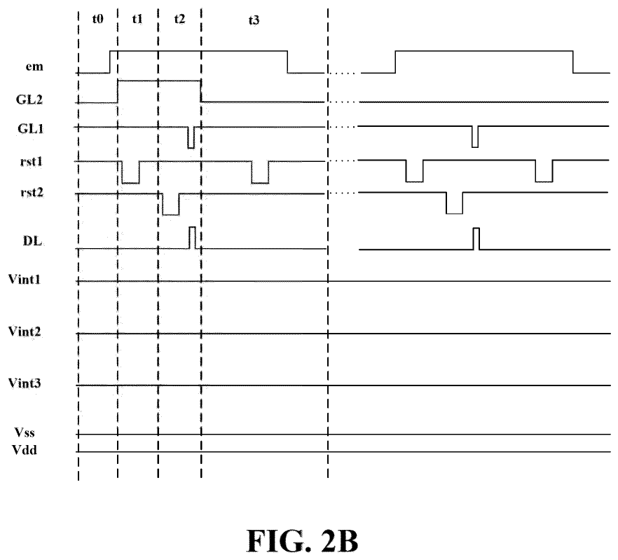

FIG. 2A is a circuit diagram illustrating the structure of a pixel driving circuit in some embodiments according to the present disclosure. Referring to FIG. 2A, in some embodiments, the pixel driving circuit includes a driving transistor Td; a storage capacitor Cst having a first capacitor electrode Ce1 and a second capacitor electrode Ce2; a second reset transistor Tr2 having a gate electrode connected to a respective second reset control signal line rst2 of a plurality of second reset control signal lines, a first electrode connected to a respective second reset signal line Vint2 of a plurality of second reset signal lines, and a second electrode connected to a second electrode of the driving transistor Td; a first transistor T1 having a gate electrode connected to a respective first gate line GL1 of a plurality of first gate lines, a first electrode connected to a respective data line DL of a plurality of data lines, and a second electrode connected to a first electrode of the driving transistor Td; a third reset transistor Tr3 having a gate electrode connected to a respective first reset control signal line rst1 of a plurality of first reset control signal lines, a first electrode connected to a respective third reset signal line Vint3 of a plurality of third reset signal lines, and a second electrode connected to the first electrode of the driving transistor Td; a second transistor T2 having a gate electrode connected to a respective second gate line GL2 of a plurality of second gate lines, a first electrode connected to the first capacitor electrode Ce1 of the storage capacitor Cst and the gate electrode of the driving transistor Td, and a second electrode connected to the second electrode of the driving transistor Td; a third transistor T3 having a gate electrode connected to a respective light emitting control signal line em of a plurality of light emitting control signal lines, a first electrode connected to a respective voltage supply line Vdd of a plurality of voltage supply lines, and a second electrode connected to the first electrode of the driving transistor Td and the second electrode of the first transistor T1; a fourth transistor T4 having a gate electrode connected to the respective light emitting control signal line em of the plurality of light emitting control signal lines, a first electrode connected to second electrodes of the driving transistor Td and the second transistor T2, and a second electrode connected to an anode of a light emitting element LE; and a first reset transistor Tr1 having a gate electrode connected to the respective first reset control signal line rst1 of a plurality of first reset control signal lines, a first electrode connected to a respective first reset signal line Vint1 of a plurality of first reset signal lines, and a second electrode connected to the second electrode of the fourth transistor T4 and the anode of the light emitting element LE. The second capacitor electrode Ce2 is connected to the respective voltage supply line and the first electrode of the third transistor T3.

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode, Accordingly, depending on the direction of the current flowing through the transistor, in one example, the first electrode is configured to receive an input signal and the second electrode is configured to output an output signal; in another example, the second electrode is configured to receive an input signal and the first electrode is configured to output an output signal.

The pixel driving circuit further include a first node N1, a second node N2, a third node N3, and a fourth node N4. The first node N1 is connected to the gate electrode of the driving transistor Td, the first capacitor electrode Ce1, and the first electrode of the second transistor T2. The second node N2 is connected to the second electrode of the third transistor T3, the second electrode of the first transistor T1, the second electrode of the third reset transistor Tr3, and the first electrode of the driving transistor Td. The third node N3 is connected to the second electrode of the driving transistor Td, the second electrode of the second transistor T2, the first electrode of the fourth transistor T4, and the second electrode of the second reset transistor Tr2. The fourth node N4 is connected to the second electrode of the fourth transistor T4, the second electrode of the first reset transistor Tr1, and the anode of the light emitting element LE.

The array substrate in some embodiments includes a plurality of subpixels. In some embodiments, the plurality of subpixels includes a respective first subpixel, a respective second subpixel, and a respective third subpixel. Optionally, a respective pixel of the array substrate includes the respective first subpixel, the respective second subpixel, and the respective third subpixel. The plurality of subpixels in the array substrate are arranged in an array. In one example, the array of the plurality of subpixels includes a S1-S2-S3 format repeating array, in which S1 stands for the respective first subpixel, S2 stands for the respective second subpixel, and S3 stands for the respective third subpixel. In another example, the S1-S2-S3 format is a C1-C2-C3 format, in which C1 stands for the respective first subpixel of a first color, C2 stands for the respective second subpixel of a second color, and C3 stands for the respective third subpixel of a third color. In another example, the C1-C2-C3 format is an R-G-B format, in which the respective first subpixel is a red subpixel, the respective second subpixel is a green subpixel, and the respective third subpixel is a blue subpixel.

In some embodiments, a minimum repeating unit of the plurality of subpixels of the array substrate includes the respective first subpixel, the respective second subpixel, and the respective third subpixel. Optionally, each of the respective first subpixel, the respective second subpixel, and the respective third subpixel, includes the first transistor T1, the second transistor T2, the third transistor T3, the fourth transistor T4, the first reset transistor Tr1, the second reset transistor Tr2, the third reset transistor Tr3, and the driving transistor Td.

The present disclosure may be implemented in pixel driving circuit having transistors of various types, including a pixel driving circuit having p-type transistors, a pixel driving circuit having n-type transistors, and a pixel driving circuit having one or more p-type transistors and one or more n-type transistors. Referring to FIG. 2A, the second transistor T2 is an n-type transistor such as a metal oxide transistor, and other transistors are p-type transistors such as polysilicon transistors. For a p-type transistor, an effective control signal (e.g., a turn-on control signal) is a low voltage signal, and an ineffective control signal (e.g., a turn-off control signal) is a high voltage signal. For an n-type transistor, an effective control signal (e.g., a turn-on control signal) is a high voltage signal, and an ineffective control signal (e.g., a turn-off control signal) is a low voltage signal.

FIG. 2B is a timing diagram illustrating the operation of a pixel driving circuit in some embodiments according to the present disclosure. Referring to FIG. 2A and FIG. 2B, during one frame of image, the operation of the pixel driving circuit includes an initial sub-phase t0, a reset sub-phase t1, a data write sub-phase t2, and a light emitting sub-phase t3. In the initial sub-phase t0, a turning-off reset control signal is provided through the respective second reset control signal line rst2 to the gate electrode of the second reset transistor Tr2 to turn off the second reset transistor Tr2. A turning-off reset control signal is provided through the respective first reset control signal line rst1 to the gate electrode of the first reset transistor Tr1 and the gate electrode of the third reset transistor Tr3 to turn off the first reset transistor Tr1 and the third reset transistor Tr3. In the initial sub-phase t0, the respective first gate line GL1 is provided with a turning-off signal, thus the first transistor T1 is turned off

In the reset sub-phase t1, a turning-on reset control signal is provided through the respective first reset control signal line rst1 to the gate electrode of the first reset transistor Tr1 to turn on the first reset transistor Tr1; allowing an initialization voltage signal from the respective first reset signal line Vint1 to pass from a first electrode of the first reset transistor Tr1 to a second electrode of the first reset transistor Tr1; and in turn to the node N4. The anode of the light emitting element LE is initialized. A turning-on reset control signal is provided through the respective first reset control signal line rst1 to the gate electrode of the third reset transistor Tr3 to turn on the third reset transistor Tr3; allowing an initialization voltage signal from the respective third reset signal line Vint3 to pass from a first electrode of the third reset transistor Tr3 to a second electrode of the third reset transistor Tr3; and in turn to the node N2. The node N2 is initialized. In the reset sub-phase t1, the respective first gate line GL1 is provided with a turning-off signal, thus the first transistor T1 is turned off The respective light emitting control signal line em is provided with a high voltage signal to turn off the third transistor T3 and the fourth transistor T4.

In the data write sub-phase t2, a turning-on reset control signal is provided through the second reset control signal line rst2 to the gate electrode of the second reset transistor Tr2 to turn on the second reset transistor Tr2; allowing an initialization voltage signal from the respective second reset signal line Vint2 to pass from a first electrode of the second reset transistor Tr2 to a second electrode of the second reset transistor Tr2, and in turn to the second electrode of the driving transistor Td. The second electrode of the driving transistor Td is initialized. The second capacitor electrode Ce2 receives a high voltage signal from the respective voltage supply line Vdd. The first capacitor electrode Ce1 is charged in the data write phase t2 due to an increasing voltage difference between the first capacitor electrode Ce1 and the second capacitor electrode Ce2.

In the data write sub-phase t2, the turning-off reset control signal is again provided through the respective first reset control signal line rst1 to the gate electrode of the first reset transistor Tr1 and the gate electrode of the third reset transistor Tr3 to turn off the first reset transistor Tr1 and the third reset transistor Tr3. The respective first gate line GL1 and the respective second gate line GL2 are provided with a turning-on signal, thus the first transistor T1 and the second transistor T2 are turned on. A second electrode of the driving transistor Td is connected with the second electrode of the second transistor T2. A gate electrode of the driving transistor Td is electrically connected with the first electrode of the second transistor T2. Because the second transistor T2 is turned on in the data write sub-phase t2, the gate electrode and the second electrode of the driving transistor Td are connected and short circuited, and only the PN junction between the gate electrode and a first electrode of the driving transistor Td is effective, thus rendering the driving transistor Td in a diode connecting mode. The first transistor T1 is turned on in the data write sub-phase t2. The data voltage signal transmitted through the respective data line DL is received by a first electrode of the first transistor T1, and in turn transmitted to the first electrode of the driving transistor Td, which is connected to the second electrode of the first transistor T1. A node N2 connecting to the first electrode of the driving transistor Td has a voltage level of the data voltage signal. Because only the PN junction between the gate electrode and a first electrode of the driving transistor Td is effective, the voltage level at the node N1 in the data write sub-phase t2 increase gradually to (Vdata+Vth), wherein the Vdata is the voltage level of the data voltage signal, and the Vth is the voltage level of the threshold voltage Th of the PN junction. The storage capacitor Cst is discharged because the voltage difference between the first capacitor electrode Ce1 and the second capacitor electrode Ce2 is reduced to a relatively small value. The respective light emitting control signal line em is provided with a high voltage signal to turn off the third transistor T3 and the fourth transistor T4.

In the light emitting sub-phase t3, the respective first gate line GL1 and the respective second gate line GL2 are provided with a turning-off signal, the first transistor T1 and the second transistor T2 are turned off. A turning-off reset control signal is provided through the respective second reset control signal line rst2 to the gate electrode of the second reset transistor Tr2 to turn off the second reset transistor Tr2. A turning-on reset control signal is provided through the respective first reset control signal line rst1 to the gate electrode of the first reset transistor Tr1 to turn on the first reset transistor Tr1; allowing an initialization voltage signal to pass to the node N4. A turning-on reset control signal is provided through the respective first reset control signal line rst1 to the gate electrode of the third reset transistor Tr3 to turn on the third reset transistor Tr3; allowing an initialization voltage signal to the node N2. The node N4 and the node N2 are initialized. Subsequently, a turning-off reset control signal is provided through the respective first reset control signal line rst1 to the gate electrode of the first reset transistor Tr1 and the gate electrode of the third reset transistor Tr3 to turn off the first reset transistor Tr1 and the third reset transistor Tr3. Subsequently, the respective light emitting control signal line em is provided with a low voltage signal to turn on the third transistor T3 and the fourth transistor T4. The voltage level at the node N1 in the light emitting sub-phase t3 is maintained at (Vdata+Vth), the driving transistor Td is turned on by the voltage level, and working in the saturation area. A path is formed through the third transistor T3, the driving transistor Td, the fourth transistor T4, to the light emitting element LE, The driving transistor Td generates a driving current for driving the light emitting element LE to emit light. A voltage level at a node N3 connected to the second electrode of the driving transistor Td equals to a light emitting voltage of the light emitting element LE.

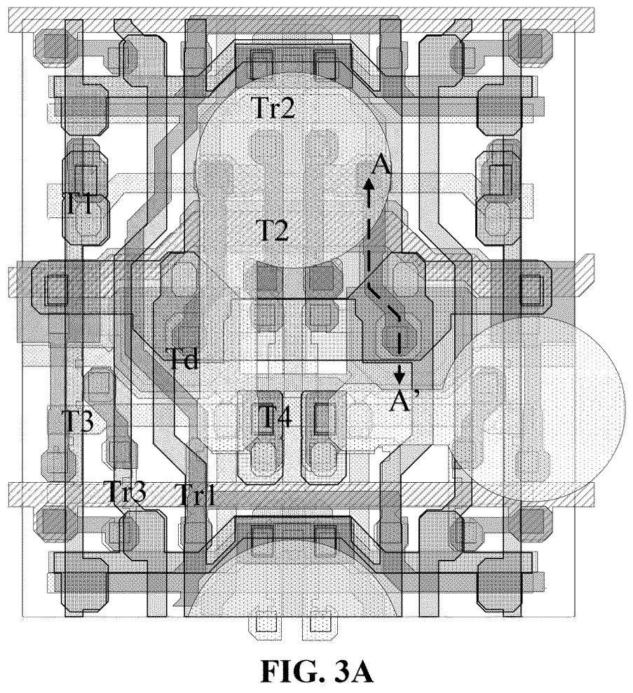

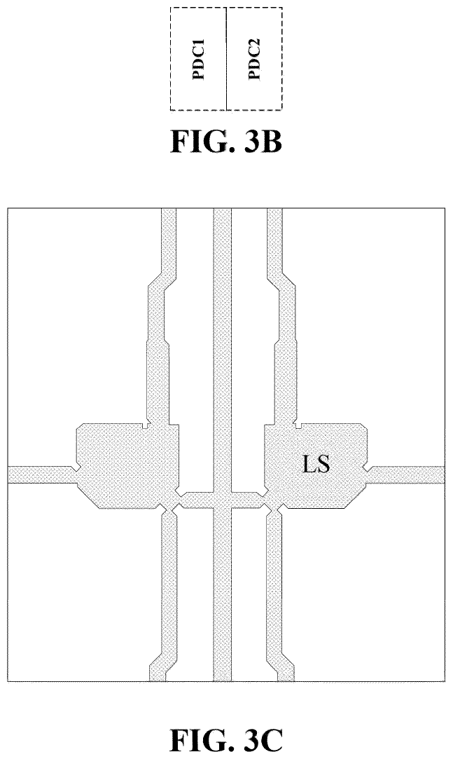

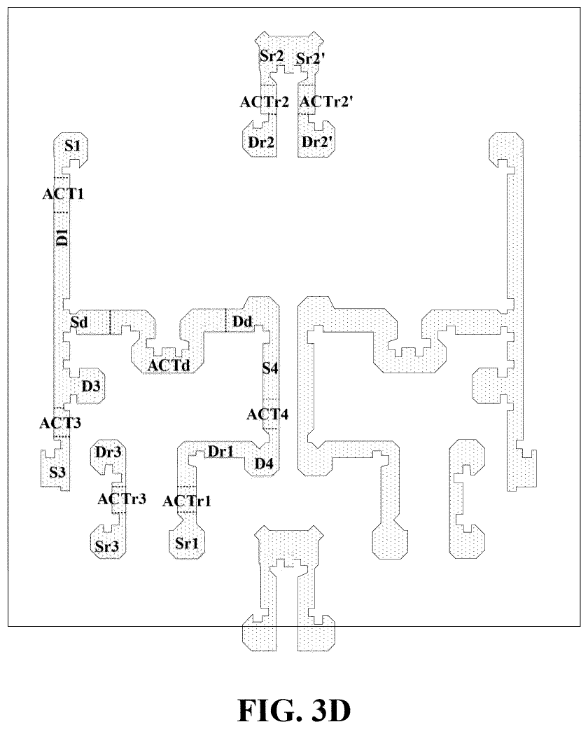

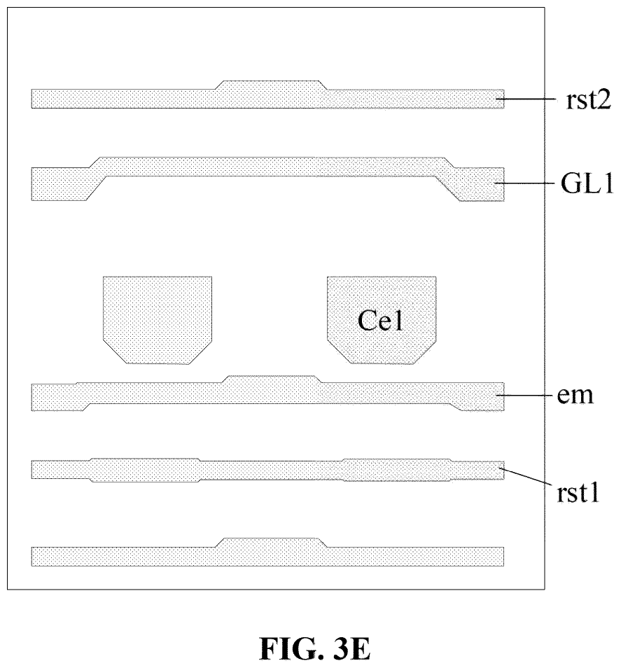

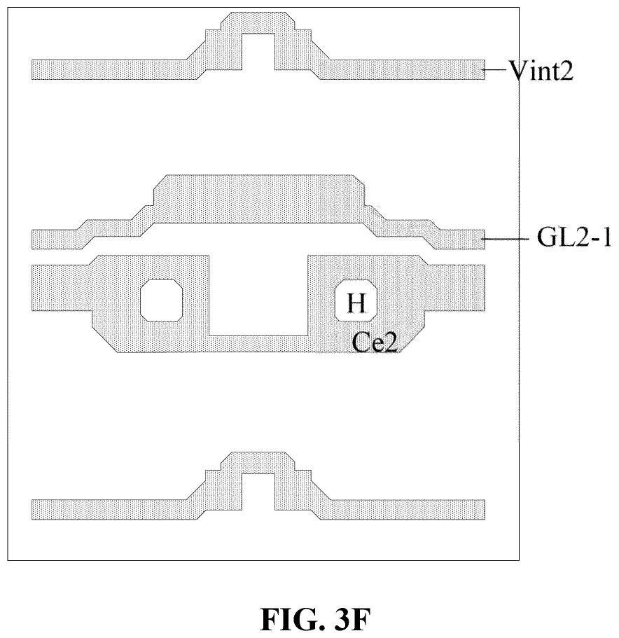

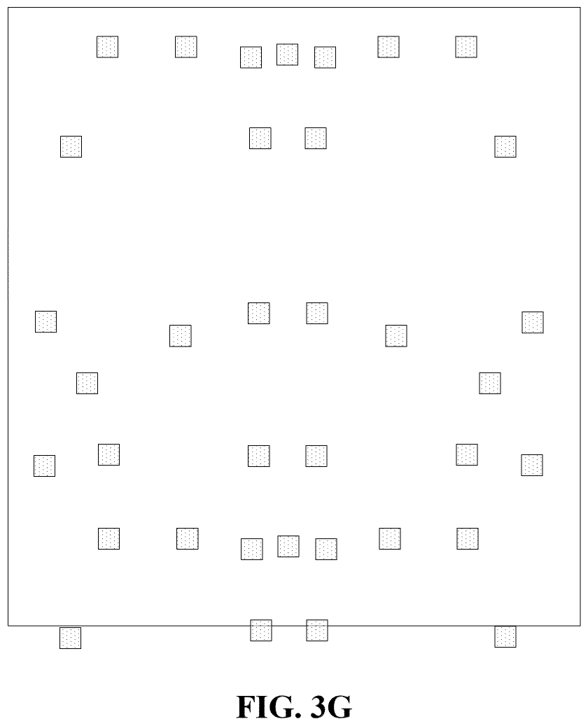

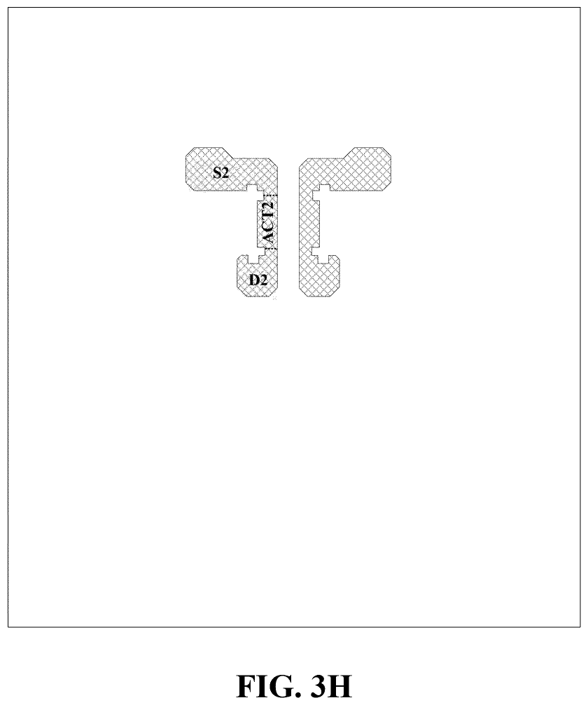

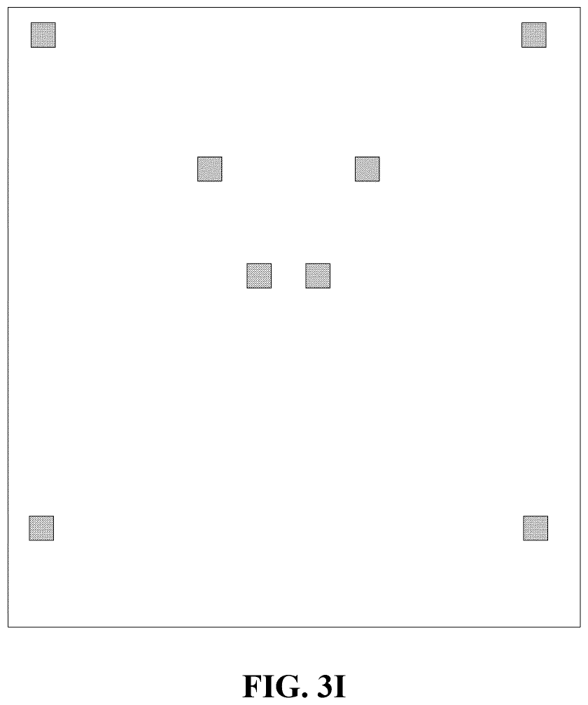

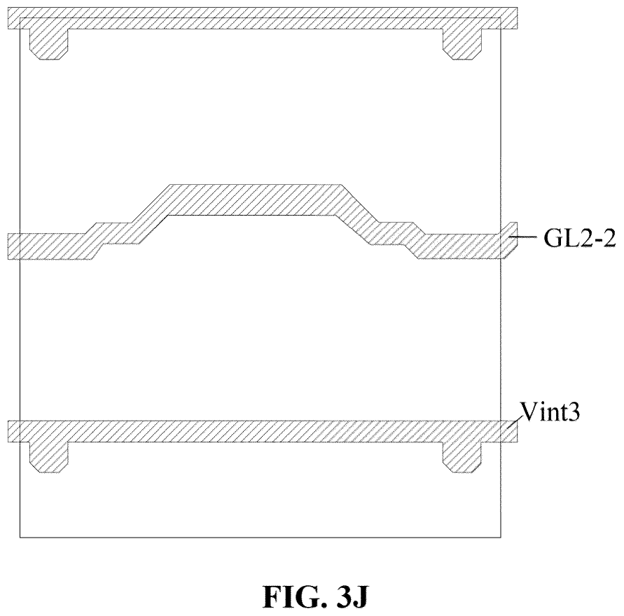

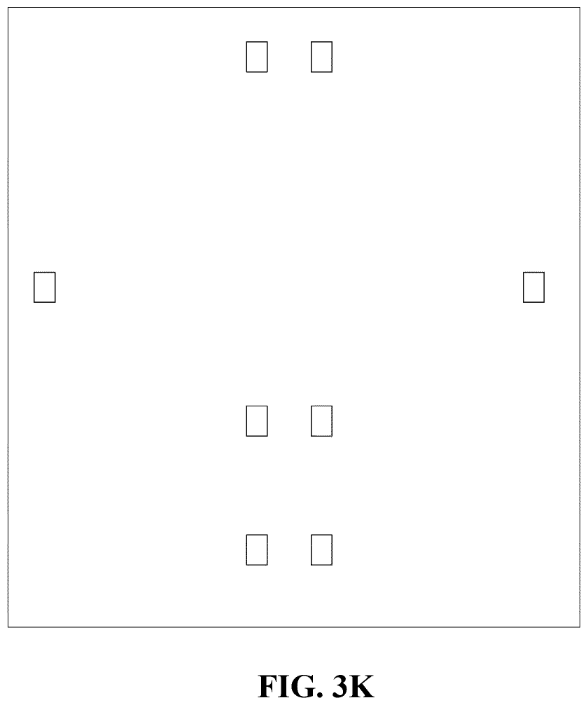

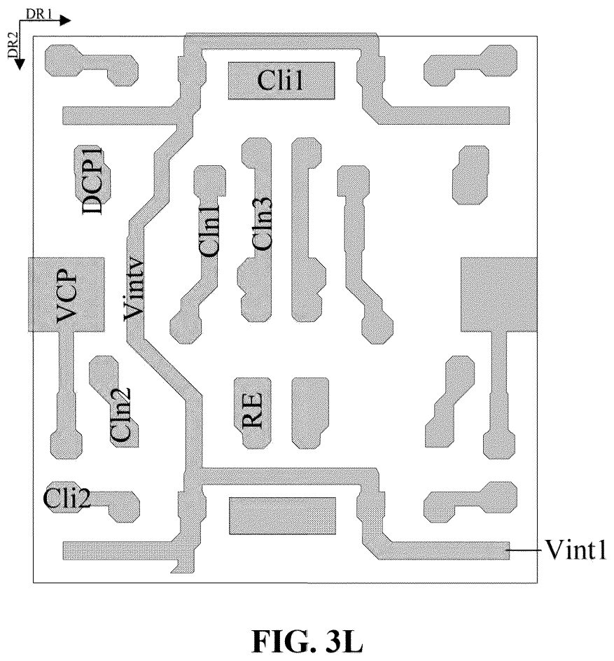

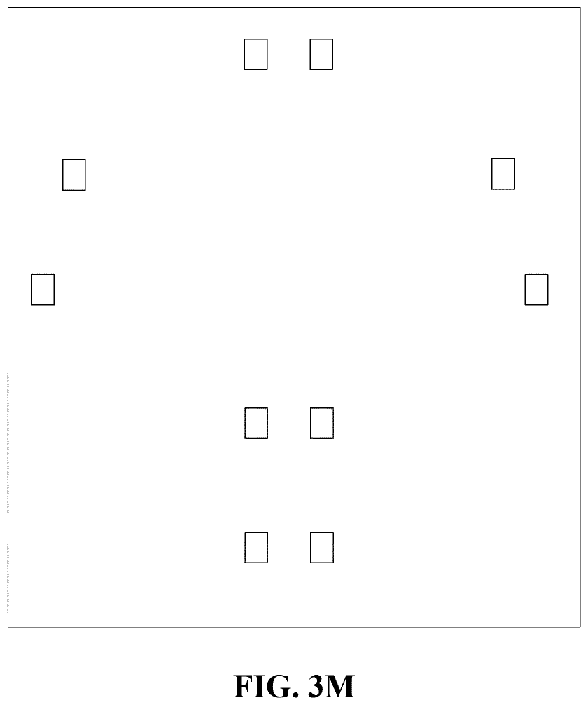

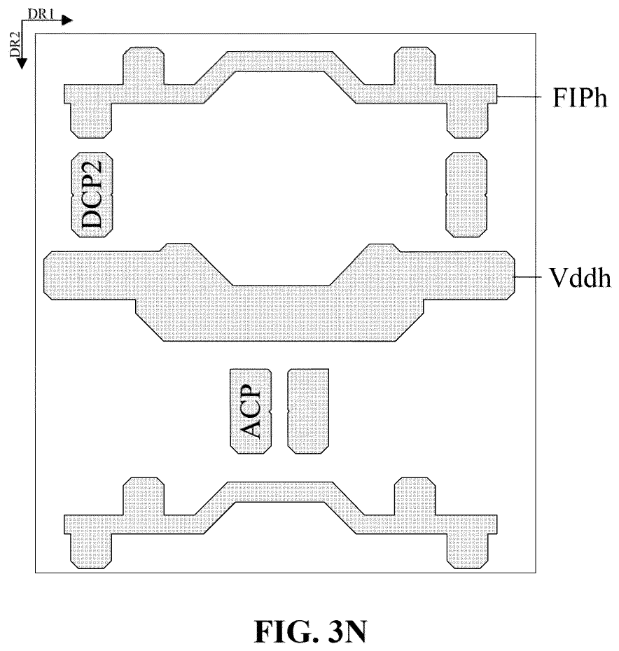

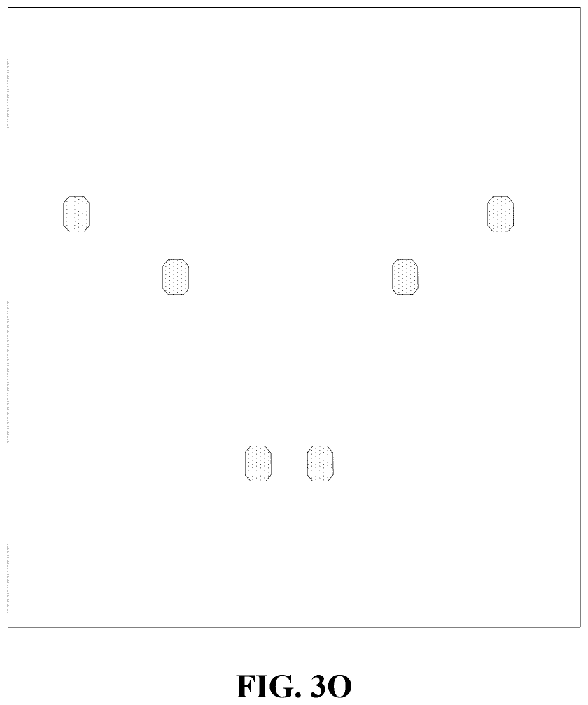

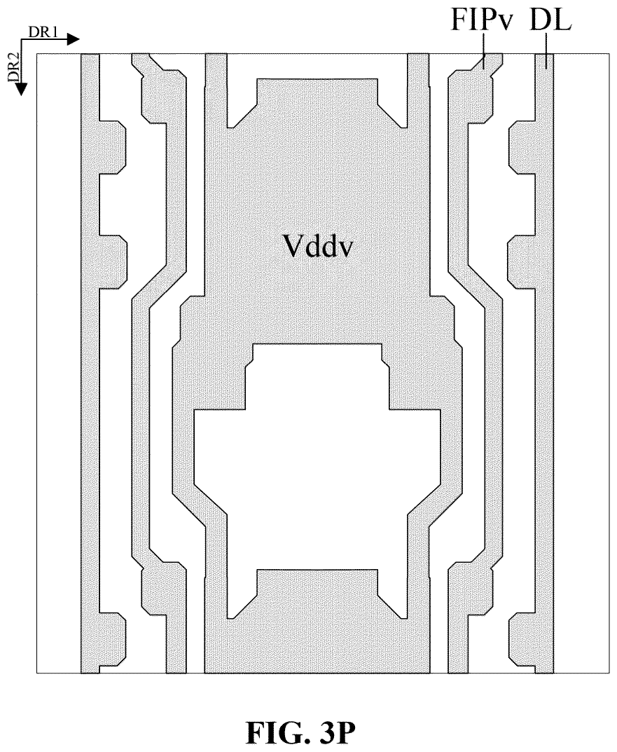

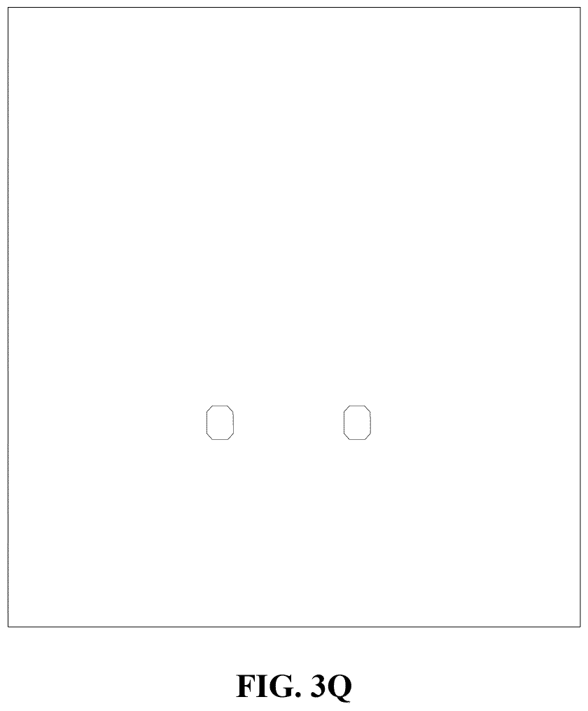

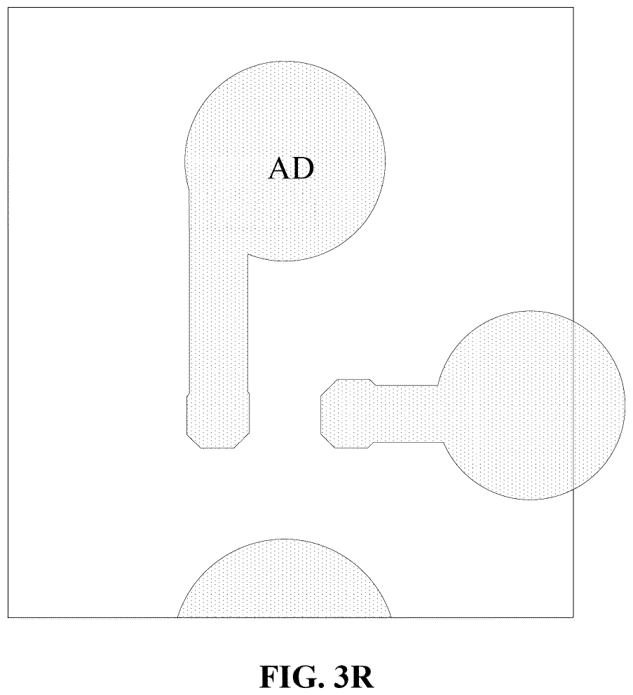

The inventors of the present disclosure discover that, with the design of the display panels evolving more and more complicated, additional layers of signal lines become necessary to accommodate the layout of the signal lines. For example, the inventors of the present disclosure discover that a third signal line layer is sometime necessary to accommodate all of the signal lines in the array substrate. FIG. 3A is a diagram illustrating the structure of an array substrate in some embodiments according to the present disclosure. FIG. 3A illustrates an example in which a third signal line layer is included.

FIG. 3B is a schematic diagram illustrating an arrangement of pixel driving circuits in an array substrate depicted in FIG. 3A. FIG. 3A and FIG. 3B depicts a portion of the array substrate having two adjacent pixel driving circuits, including PDC1 and PDC2.

FIG. 3C is a diagram illustrating the structure of a light shielding layer in the array substrate depicted in FIG. 3A. FIG. 3D is a diagram illustrating the structure of a first semiconductor material layer in the array substrate depicted in FIG. 3A. FIG. 3E is a diagram illustrating the structure of a first gate metal layer in the array substrate depicted in FIG. 3A. FIG. 3F is a diagram illustrating the structure of a second gate metal layer in the array substrate depicted in FIG. 3A. FIG. 3G is a diagram illustrating vias extending through a first inter-layer dielectric layer in the array substrate depicted in FIG. 3A. FIG. 3H is a diagram illustrating the structure of a second semiconductor material layer in the array substrate depicted in FIG. 3A. FIG. 3I is a diagram illustrating vias extending through a second inter-layer dielectric layer in the array substrate depicted in FIG. 3A. FIG. 3J is a diagram illustrating the structure of a third gate metal layer in the array substrate depicted in FIG. 3A. FIG. 3K is a diagram illustrating vias extending through a passivation layer in the array substrate depicted in FIG. 3A. FIG. 3L is a diagram illustrating the structure of a first signal line layer in the array substrate depicted in FIG. 3A. FIG. 3M is a diagram illustrating vias extending through a first planarization layer in the array substrate depicted in FIG. 3A. FIG. 3N is a diagram illustrating the structure of a second signal line layer in the array substrate depicted in FIG. 3A. FIG. 3O is a diagram illustrating vias extending through a second planarization layer in the array substrate depicted in FIG. 3A. FIG. 3P is a diagram illustrating the structure of a third signal line layer in the array substrate depicted in FIG. 3A. FIG. 3Q is a diagram illustrating vias extending through a third planarization layer in the army substrate depicted in FIG. 3A. FIG. 3R is a diagram illustrating an anode layer in the array substrate depicted in FIG. 3A. FIG. 4 is a cross-sectional view along an A-A′ line in FIG. 3A.

Referring to FIG. 3A to FIG. 3R, and FIG. 4, the array substrate in some embodiments includes a base substrate BS, a light shield layer LS on the base substrate BS, a buffer layer BUF on a side of the light shield layer LS away from the base substrate BS, a first semiconductor material layer SML1 on a side of the buffer layer BUF away from the base substrate BS, a gate insulating layer GI on a side of the first semiconductor material layer SML1 away from the base substrate BS, a first gate metal layer Gate1 on a side of the gate insulating layer GI away from the first semiconductor material layer SML1, an insulating layer IN on a side of the first gate metal layer Gate1 away from the gate insulating layer GI, a second gate metal layer Gate2 on a side of the insulating layer IN away from the first gate metal layer Gate1, a first inter-layer dielectric layer ILD1 on a side of the second gate metal layer Gate2 away from the insulating layer IN, a second semiconductor material layer SML2 on a side of the first inter-layer dielectric layer ILD1 away from the second gate metal layer Gate2, a second inter-layer dielectric layer ILD2 on a side of the second semiconductor material layer SML2 away from the first inter-layer dielectric layer ILD1, a third gate metal layer Gate3 on a side of the second inter-layer dielectric layer ILD2 away from the second semiconductor material layer SML2, a passivation layer PVX on a side of the third gate metal layer Gate3 away from the second inter-layer dielectric layer ILD2, a first signal line layer SD1 on a side of the passivation layer PVX away from the third gate metal layer Gate3, a first planarization layer PLN1 on a side of the first signal line layer SD1 away from the passivation layer PVX, a second signal line layer SD2 on a side of the first planarization layer PLN1 away from the first signal line layer SD1, a second planarization layer PLN2 on a side of the second signal line layer SD2 away from the first planarization layer PLN1, a third signal line layer SD3 on a side of the second planarization layer PLN2 away from the second signal line layer SD2, a third planarization layer PLN3 on a side of the third signal line layer SD3 away from the second planarization layer PLN2, and an anode layer ADL on a side of the third planarization layer PLN3 away from the third signal line layer SD3.

Referring to FIG. 2A, FIG. 3A, FIG. 3C, and FIG. 4, in some embodiments, the light shield layer LSL includes a light shield LS. Various appropriate materials and various appropriate fabricating methods may be used for making the light shield layer LS. For example, a metallic material may be deposited on the substrate by a plasma-enhanced chemical vapor deposition (PECVD) process. Examples of appropriate metallic materials for making the light shield layer LS include, but are not limited to, aluminum, chromium, tungsten, titanium, tantalum, molybdenum, copper, and alloys or laminates containing the same.

Referring to FIG. 2A, FIG. 3A, FIG. 3D, and FIG. 4, the first semiconductor material layer SML1 in some embodiments includes at least active layers of multiple transistors of the pixel driving circuit, including the first transistor T1, the third transistor T3, the fourth transistor T4, the first reset transistor Tr1, the second reset transistor Tr2, the third reset transistor Tr3, and the driving transistor Td. Optionally, the first semiconductor material layer SML1 further includes at least respective portions of first electrodes of multiple transistors of the pixel driving circuit, including the first transistor T1, the third transistor T3, the fourth transistor T4, the first reset transistor Tr1, the second reset transistor Tr2, the third reset transistor Tr3, and the driving transistor Td. Optionally, the first semiconductor material layer SML1 further includes at least respective portions of second electrodes of multiple transistors of the pixel driving circuit, including the first transistor T1, the third transistor T3, the fourth transistor T4, the first reset transistor Tr1, the second reset transistor Tr2, the third reset transistor Tr3, and the driving transistor Td. Optionally, the first semiconductor material layer SML1 includes active layers, first electrodes, and second electrodes of multiple transistors of the pixel driving circuit, including the first transistor T1, the third transistor T3, the fourth transistor T4, the first reset transistor Tr1, the second reset transistor Tr2, the third reset transistor Tr3, and the driving transistor Td. Various appropriate semiconductor materials may be used for making the first semiconductor material layer SML1. Examples of the semiconductor materials for making the first semiconductor material layer SML1 include silicon-based semiconductor materials such as polycrystalline silicon, single-crystal silicon, and amorphous silicon.

In FIG. 3D, a pixel driving circuit corresponding to PDC1 in FIG. 3B is annotated with labels indicating components of each of multiple transistors (T1, T3, T4, Tr1, Tr2, Tr3, and Td) in the pixel driving circuit. For example, the first transistor T1 includes an active layer ACT1, a first electrode S1, and a second electrode D1. The third transistor T3 includes an active layer ACT3, a first electrode S3, and a second electrode D3. The fourth transistor T4 includes an active layer ACT4, a first electrode S4, and a second electrode D4. The first reset transistor Tr1 includes an active layer ACTr1, a first electrode Sr1, and a second electrode Dr1. The second reset transistor Tr2 includes an active layer ACTr2, a first electrode Sr2, and a second electrode Dr2. The third reset transistor Tr3 includes an active layer ACTr3, a first electrode Sr3, and a second electrode Dr3. The driving transistor Td includes an active layer ACTd, a first electrode Sd, and a second electrode Dd.

Optionally, the active layers (ACT1, ACT3, ACT4, ACTr1, ACTr2, ACTr3, and ACTd), the first electrodes (S1, S3, S4, Sr1, Sr2, Sr3, and Sd), and the second electrodes (D1, D3, D4, Dr1, Dr2, Dr3, and Dd) of the respective transistors (T1, T3, T4, Tr1, Tr2, Tr3, and Td) are in a same layer.

In some embodiments, the active layers (ACT1, ACT3, ACT4, ACTr1, and ACTd), at least portions of the first electrodes (S1, S3, S4, Sr1, and Sd), and at least portions of the second electrodes (D1, D3, D4, Dr1, and Dd) of multiple transistors (T1, T3, T4, Tr1, and Td) in the pixel driving circuit are parts of a unitary structure. Optionally, a part of the second reset transistor Tr2 (ACTr2, Sr2, Dr2) in the first semiconductor material layer is spaced apart from the unitary structure (T1, T3, T4, Tr1, and Td) in a same pixel driving circuit. Optionally, a part of the third reset transistor Tr3 (ACTr3, Sr3, Dr3) in the first semiconductor material layer is spaced apart from the unitary structure (T1, T3, T4, Tr1, and Td) in a same pixel driving circuit.

In some embodiments, the active layers (ACTr2 and ACTr2′), at least portions of the first electrodes (Sr2 and Sr2′), and at least portions of the second electrodes (Dr2 and Dr2′) of second reset transistors in two adjacent pixel driving circuits in a row are parts of a unitary structure. Optionally, the first electrodes (Sr2 and Sr2′) of the two adjacent pixel driving circuits in a row are directly connected to each other.

Referring to FIG. 2A, FIG. 3A, FIG. 3E, and FIG. 4, the first gate metal layer Gate1 in some embodiments includes a plurality of first gate lines (e.g., a respective first gate line GL1), a plurality of first reset control signal lines (e.g., a respective first reset control signal line rst1), a plurality of second reset control signal lines (e.g. a respective second reset control signal line rst2), a plurality of light emitting control signal lines (e.g., a respective light emitting control signal line em), and a first capacitor electrode Ce1 of the storage capacitor Cst in the pixel driving circuit.

Various appropriate electrode materials and various appropriate fabricating methods may be used to make the first gate metal layer Gate1. For example, a conductive material may be deposited on the substrate by a plasma-enhanced chemical vapor deposition (PECVD) process and patterned. Examples of appropriate conductive materials for making the first gate metal layer Gate1 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of first gate lines (e.g., the respective first gate line GL1), the plurality of first reset control signal lines (e.g., the respective first reset control signal line rst1), the plurality of second reset control signal lines (e.g., the respective second reset control signal line rst2), the plurality of light emitting control signal lines (e.g., the respective light emitting control signal line em), and the first capacitor electrode Ce1 of the storage capacitor Cst in the pixel driving circuit are in a same layer.

As used herein, the term “same layer” refers to the relationship between the layers simultaneously formed in the same step. In one example, the plurality of light emitting control signal lines and the first capacitor electrode Ce1 are in a same layer when they are formed as a result of one or more steps of a same patterning process performed in a same layer of material. In another example, the plurality of light emitting control signal lines and the first capacitor electrode Ce1 can be formed in a same layer by simultaneously performing the step of forming the plurality of light emitting control signal lines, and the step of forming the first capacitor electrode Ce1. The term “same layer” does not always mean that the thickness of the layer or the height of the layer in a cross-sectional view is the same.

Referring to FIG. 2A, FIG. 3A, FIG. 3F, and FIG. 4, the second gate metal layer Gate2 in some embodiments includes at least portions of a plurality of second gate lines (e.g., a respective second gate line first branch GL2-1), a plurality of second reset signal lines (e.g., a respective second reset signal Vint2), and a second capacitor electrode Ce2 of the storage capacitor Cst in the pixel driving circuit. Various appropriate electrode materials and various appropriate fabricating methods may be used to make the second gate metal layer Gate2. For example, a conductive material may be deposited on the substrate by a plasma-enhanced chemical vapor deposition (PECVD) process and patterned. Examples of appropriate conductive materials for making the second gate metal layer Gate2 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the at least portions of the plurality of second gate lines (e.g., a respective second gate line first branch GL2-1), the plurality of second reset signal lines (e.g., the respective second reset signal Vint2), and the second capacitor electrode Ce2 of the storage capacitor Cst in the pixel driving circuit are in a same layer.

Referring to FIG. 3F, a plurality of second capacitor electrodes in a plurality of pixel driving circuits are connected to each other, and are parts of a unitary structure. By having second capacitor electrodes connected to each other, a resistance of a respective first voltage supply line Vddh can be reduced because the second capacitor electrodes are electrically connected to the respective first voltage supply line Vddh. The inventors of the present disclosure discover that this structure improves display uniformity in the array substrate.

In alternative embodiments, the plurality of second capacitor electrodes in the plurality of pixel driving circuits are spaced apart from each other. By having second capacitor electrodes spaced apart from each other, parasitic capacitance between the plurality of second capacitor electrodes and the second electrode Dd of the driving transistor Td (e.g., the node N3) can be reduced, preventing occurrence of short-term residual image when the array substrate is in a display mode.

Vias extending through the first inter-layer dielectric layer ILD1 are depicted in FIG. 3G.

Referring to FIG. 2A, FIG. 3A, FIG. 3H, and FIG. 4, the second semiconductor material layer SML2 in some embodiments includes at least an active layer ACT2 of the second transistor T2 in the pixel driving circuit. Optionally, the second semiconductor material layer SML2 further includes at least a portion of a first electrode S2 of the second transistor T2 in the pixel driving circuit. Optionally, the second semiconductor material layer SML2 further includes at least a portion of a second electrode D2 of the second transistor T2 in the pixel driving circuit. Optionally, the second semiconductor material layer SML2 includes the active layer ACT2, the first electrode S2, and the second electrode D2 of the second transistor T2. In the present array substrate, at least the active layer ACT2 of the second transistor T2 are in a layer different from at least the active layers of other transistors of the pixel driving circuit. Various appropriate semiconductor materials may be used for making the second semiconductor material layer SML2. Examples of the semiconductor materials for making the second semiconductor material layer SML2 include metal oxide-based semiconductor material such as indium gallium zinc oxide and metal oxynitride-based semiconductor materials such as zinc oxynitride.

In FIG. 3H, a pixel driving circuit corresponding to PDC1 in FIG. 3B is annotated with labels indicating components of the second transistor in the pixel driving circuit. For example, the second transistor T2 includes an active layer ACT2, a first electrode S2, and a second electrode D2. Optionally, the active layer ACT2, the first electrode S2, and the second electrode D2 of the second transistor T2 are in a same layer.

Vias extending through the second inter-layer dielectric layer ILD2 are depicted in FIG. 3I.

Referring to FIG. 2A, FIG. 3A, FIG. 3J, and FIG. 4, the third gate metal layer Gate3 in some embodiments includes at least portions of a plurality of second gate lines (e.g., a respective second gate line second branch GL2-2), and a plurality of third reset signal lines (e.g., a respective third reset signal line Vint3). Various appropriate electrode materials and various appropriate fabricating methods may be used to make the third gate metal layer Gate3. For example, a conductive material may be deposited on the substrate by a plasma-enhanced chemical vapor deposition (PECVD) process and patterned. Examples of appropriate conductive materials for making the third gate metal layer Gate3 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like.

Vias extending through the passivation layer PVX are depicted in FIG. 3K.

Referring to FIG. 2A, FIG. 3A, FIG. 3L, and FIG. 4, the first signal line layer SD1 in some embodiments includes a plurality of first reset signal lines (e.g., a respective first reset signal line Vint1); a plurality of fourth reset signal lines (e.g., a respective fourth reset signal line Vintv); a first data connecting pad DCP1; a voltage connecting pad VCP; a first node connecting line Cln1; a second node connecting line Cln2; a third node connecting line Cln3; a relay electrode RE; a first reset signal connecting line Cli1; and a second reset signal connecting line Cli2. In some embodiments, the plurality of first reset signal lines and the plurality of fourth reset signal lines form an interconnected reset signal network configured to provide a reset signal to a plurality of pixel driving circuits in the array substrate.

Various appropriate conductive materials and various appropriate fabricating methods may be used to make the first signal line layer SD1. For example, a conductive material may be deposited on the substrate by a plasma-enhanced chemical vapor deposition (PECVD) process and patterned. Examples of appropriate conductive materials for making the first signal line layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of first reset signal lines (e.g., the respective first reset signal line Vint1); the plurality of fourth reset signal lines (e.g., the respective fourth reset signal line Vintv); the first data connecting pad DCP1; the voltage connecting pad VCP; the first node connecting line Cln1; the second node connecting line Cln2; the third node connecting line Cln3; the relay electrode RE; the first reset signal connecting line Cli1; and the second reset signal connecting line Cli2 are in a same layer.

In some embodiments, the first node connecting line Cln1 connects multiple components of the pixel driving circuit to the node N1. Referring to FIG. 4, the first node connecting line Cln1 is connected to the first capacitor electrode Ce1 through a first via v1, and connected to the second transistor T2 (e.g., to the first electrode S2 of the second transistor T2) through a second via v2. Optionally, the first node connecting line Cln1 corresponds to the node N1 depicted in FIG. 2A.

Referring to FIG. 2A, FIG. 3A, FIG. 3E, FIG. 3F, and FIG. 4, in some embodiments, in a hole region H, a portion of the second capacitor electrode Ce2 is absent. Optionally, an orthographic projection of the second capacitor electrode Ce2 on a base substrate BS substantially (e.g., at least 80%, at least 85%, at least 90%, at least 95%, at least 98%, at least 99%, or 100%) covers, with a margin, an orthographic projection of the first capacitor electrode Ce1 on the base substrate BS except for the hole region H in which a portion of the second capacitor electrode Ce2 is absent. Optionally, the first via v1 extends through the passivation layer PVX, the second inter-layer dielectric layer ILD2, the first inter-layer dielectric layer ILD1, the hole region H, and the insulating layer IN.

In some embodiments, the first node connecting line Cln1 crosses over a respective second gate line of the plurality of second gate lines. As shown in FIG. 3A and FIG. 4, the first node connecting line Cln1 crosses over the respective second gate line first branch GL2-1 in the second gate metal layer Gate2, and the respective second gate line second branch GL2-2 in the third gate metal layer Gate3.

Referring to FIG. 3A, FIG. 3N, and FIG. 3P, in some embodiments, the respective first voltage supply line Vddh extends along a direction substantially parallel to the first direction DR1, and the respective second voltage supply line Vddv extends along a direction substantially parallel to the second direction DR2. Optionally, the plurality of first voltage supply lines and the plurality of second voltage supply lines form an interconnected voltage supply network. The first direction DR1 and the second direction DR2 are different from each other. As used herein, the term “substantially parallel” means that an angle is in the range of 0 degree to approximately 45 degrees, e.g., 0 degree to approximately 5 degrees, 0 degree to approximately 10 degrees, 0 degree to approximately 15 degrees, 0 degree to approximately 20 degrees, 0 degree to approximately 25 degrees, 0 degree to approximately 30 degrees.

Vias extending through the first planarization layer PLN1 are depicted in FIG. 3M.

Referring to FIG. 2A, FIG. 3A, FIG. 3N, and FIG. 4, the second signal line layer SD2 in some embodiments includes a plurality of first voltage supply lines (e.g., the respective first voltage supply line Vddh), a second data connecting pad DCP2, an anode connecting pad ACP, and a plurality of first fanout connecting lines (e.g., a respective first fanout connecting line FIPh). Various appropriate conductive materials and various appropriate fabricating methods may be used to make the second signal line layer SD2, For example, a conductive material may be deposited on the substrate by a plasma-enhanced chemical vapor deposition (PECVD) process and patterned. Examples of appropriate conductive materials for making the second signal line layer SD2 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of first voltage supply lines (e.g., the respective first voltage supply line Vddh), the second data connecting pad DCP2, the anode connecting pad ACP, and the plurality of first fanout connecting lines (e.g., the respective first fanout connecting line FIPh) are in a same layer.

Vias extending through the second planarization layer PLN2 are depicted in FIG. 3O.

Referring to FIG. 2A, FIG. 3A, FIG. 3P, and FIG. 4, the third signal line layer SD3 in some embodiments includes a plurality of second voltage supply lines (e.g., the respective second voltage supply line Vddv), a plurality of data lines (e.g., a respective data line DL), and a plurality of second fanout connecting lines (e.g., a respective second fanout connecting line FIPv). Various appropriate conductive materials and various appropriate fabricating methods may be used to make the third signal line layer SD3. For example, a conductive material may be deposited on the substrate by a plasma-enhanced chemical vapor deposition (PECVD) process and patterned. Examples of appropriate conductive materials for making the third signal line layer SD3 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of second voltage supply lines (e.g., the respective second voltage supply line Vddv), the plurality of data lines (e.g., the respective data line DL), and the plurality of second fanout connecting lines (e.g., the respective second fanout connecting line FIPv) are in a same layer.

The plurality of first fanout connecting lines and the plurality of second fanout connecting lines are configured to connect the plurality of data lines to a data driving circuit. By having the fanout connecting lines at least partially in a display area of the array substrate, the array substrate can have a decreased peripheral area.

In some embodiments, the respective first fanout connecting line FIPh extends along a direction substantially parallel to the first direction DR1, and the respective second voltage supply line Vddv extends along a direction substantially parallel to the second direction DR2.

Vias extending through the third planarization layer PLN3 are depicted in FIG. 3Q.

Referring to FIG. 2A, FIG. 3A, FIG. 3R, and FIG. 4, the anode layer ADL in some embodiments includes a plurality of anodes AD.

The inventors of the present disclosure further discover that a degree of evenness of anodes in a display panel could adversely affect image display, For example, color separation may result from the anodes being tilted. It is discovered in the present disclosure that signal lines underneath the anodes could significantly affect the degree the anodes being titled. In one example, underneath an anode, at one side a signal line is disposed while the other side is absent of a signal line. This results in an uneven surface of a planarization layer on top of the signal line. The uneven surface of the planarization layer in turn results in the anode on top of the planarization layer being tilted. For example, the presence of a signal line underneath a left side portion of a planarization layer results in an uneven surface of the planarization layer, which in turn results in an anode on top of the planarization layer being titled toward the right side. The titled anode reflects more light toward the right side of the display panel, In the display panel, anodes associated with subpixels of different colors have different titled angles, thus light reflected by anodes in subpixels of different colors reflect light of different colors respectively at different angles. The accumulated effect of this issue lead to color separation at a large viewing angle.

The inventors of the present disclosure further discover that, with the development of color on encapsulation technology, the color separation issue due to the unevenness of the surface on which the anodes are placed becomes more prominent.

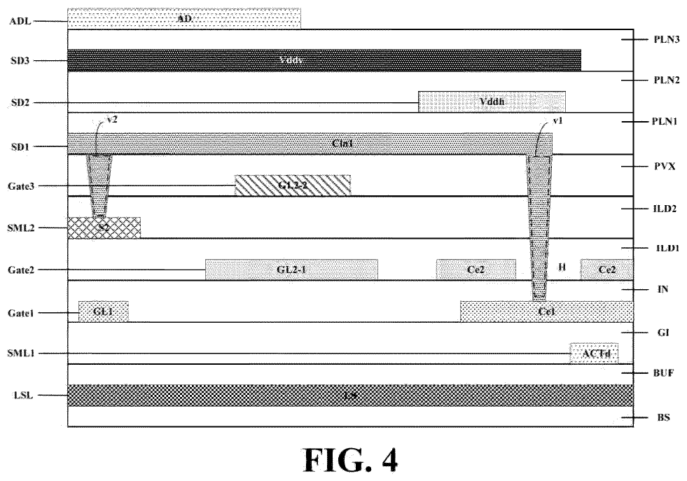

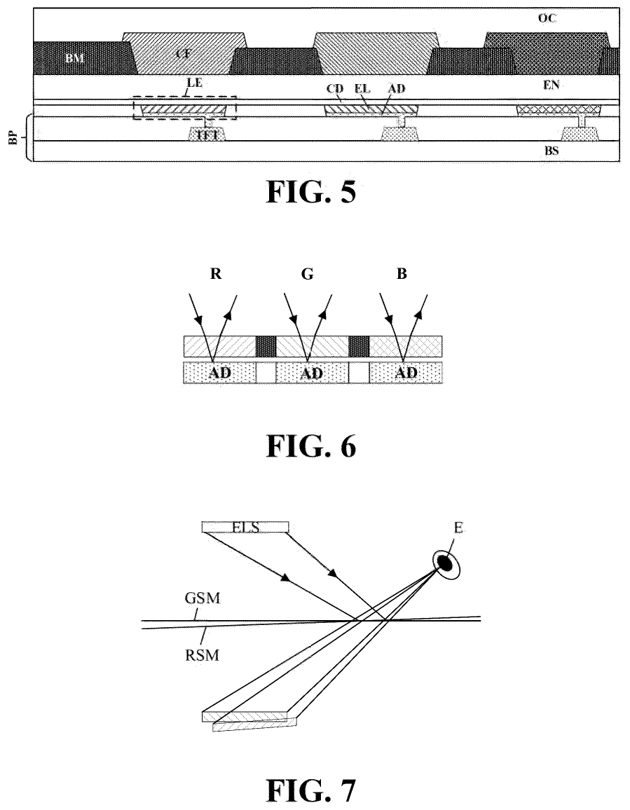

FIG. 5 is a schematic diagram illustrating the structure of an array substrate in some embodiments according to the present disclosure. Referring to FIG. 5, the array substrate in some embodiments includes a base substrate BS, a plurality of thin film transistors TFT on the base substrate BS, a plurality of light emitting elements LE on a side of the plurality of thin film transistors TFT away from the base substrate BS, an encapsulating layer EN on a side of the plurality of light emitting elements LE away from the base substrate BS, a black matric BM and a color filter CF on a side of the encapsulating layer EN away from the plurality of light emitting elements LE, and an overcoat layer OC on a side of the black matric BM and the color filter CF away from the encapsulating layer EN. A respective light emitting element of the plurality of light emitting elements LE includes a respective anode of a plurality of anodes AD, a light emitting layer EL on a side of the respective anode away from the base substrate BS, and a cathode CD on a side of the light emitting layer EL away from the respective anode. The respective anode is connected to a respective thin film transistor of the plurality of thin film transistors TFT. In one example, the array substrate depicted in FIG. 4 corresponds to a back plate BP of the array substrate depicted in FIG. 5, wherein the back plate BP includes the plurality of thin film transistors TFT and the plurality of anodes AD.

FIG. 6 illustrates light reflection by an anode in a related array substrate. FIG. 6 illustrates a red subpixel R, a green subpixel G, and a blue subpixel B. As shown in FIG. 6, ambient light enters a subpixel, and is reflected by the respective anode in the subpixel.

FIG. 7 illustrates occurrence of color separation in a related array substrate, Referring to FIG. 7, when the array substrate is in a black screen state, light from an external light source ELS irradiates on the array substrate, and is reflected by the anode (acting as a mirror). FIG. 7 illustrates a green subpixel matrix GSM and a red subpixel matrix RSM. The external light enters the green subpixel matrix GSM, and is reflected by anodes in the green subpixel matrix GSM. The external light reflected by the anodes in the green subpixel matrix GSM is filtered by green color filter at least once, and is converted into green light. The external light enters the red subpixel matrix RSM, and is reflected by anodes in the red subpixel matrix RSM. The external light reflected by the anodes in the red subpixel matrix RSM is filtered by red color filter at least once, and is converted into red light. When an observer's eye E looks at the displayed image, it perceives the images formed by the reflected green and red lights. However, due to the differential tilts of the anodes in the green subpixel matrix GSM compared to the anodes in the red subpixel matrix RSM, the observer's eye E sees two separate images: a green image and a red image. This discrepancy in the tilts of the anodes leads to a color separation in the displayed image, where the green and red components appear to be slightly separated or misaligned.

Accordingly, the present disclosure provides, inter alia, an array substrate and a display apparatus that substantially obviate one or more of the problems due to limitations and disadvantages of the related art. In one aspect, the present disclosure provides an array substrate. In some embodiments, the array substrate includes a base substrate; a signal line layer closest to an anode on the base substrate; an anode layer on a side of the signal line layer closest to the anode away from the base substrate; a pixel definition layer; and a plurality of subpixel apertures extending through the pixel definition layer. Optionally, the anode layer includes a plurality of anodes. Optionally, the signal line layer closest to the anode comprises a plurality of signal lines. Optionally, an orthographic projection of a portion of a respective anode of the plurality of anodes in a respective subpixel aperture of the plurality of subpixel apertures on a base substrate at least partially overlaps with an orthographic projection of the signal line layer closest to the anode on the base substrate, forming one or more overlapping areas. Optionally, the one or more overlapping areas have a substantial mirror symmetry with respect to a plane perpendicular to the respective anode and intersecting the respective anode.

The inventors of the present disclosure discover that the color separation issue is at least partially due to an uneven surface of a planarization layer on top of a signal line layer that is on a side of the anode closer to the plurality of thin film transistor, and the signal line layer is a signal line layer closest to the anode. In one example, the signal line layer that is closest to the anode and on a side of the anode closer to the plurality of thin film transistor is a third signal line layer, and the planarization layer between the anode and the signal line layer is a third planarization layer. In another example, the signal line layer that is closest to the anode and on a side of the anode closer to the plurality of thin film transistor is a second signal line layer, and the planarization layer between the anode and the signal line layer is a second planarization layer. In another example, the signal line layer that is closest to the anode and on a side of the anode closer to the plurality of thin film transistor is a first signal line layer, and the planarization layer between the anode and the signal line layer is a first planarization layer.

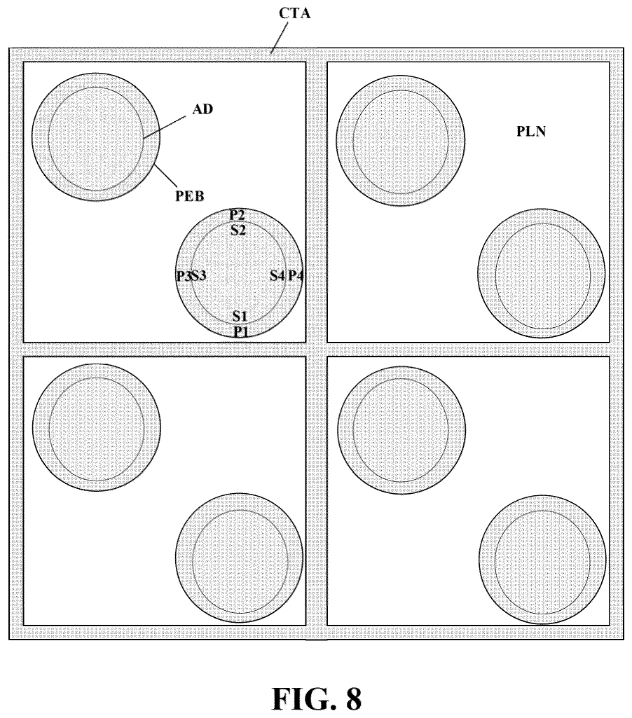

The inventors of the present disclosure discover that, by having an intricate relative layout between the anode and the signal line layer closest to the anode, the array substrate achieves an even surface of the planarization layer underneath the anodes (for example, the planarization layer PLN depicted in FIG. 8). As a result, color separation issue can be alleviated. FIG. 8 illustrates a relative layout between an anode layer and a signal line layer closest to the anode in an array substrate in some embodiments according to the present disclosure. Referring to FIG. 8, the array substrate in some embodiments includes a signal line layer CTA closest to an anode, a planarization layer PLN on the signal line layer CTA closest to the anode, and a plurality of anodes AD on a side of the planarization layer PLN away from the signal line layer CTA closest to the anode. As shown in FIG. 8, the signal line layer CTA closest to the anode in some embodiments includes a plurality of planarization enhancing blocks PEB. A respective anode of the plurality of anodes AD is on a side of the planarization layer PLN away from a respective planarization enhancing block of the plurality of planarization enhancing blocks PEB. In some embodiments, an orthographic projection of the respective planarization enhancing block on the planarization layer PLN substantially covers (e.g., covers at least 80%, covers at least 85%, covers at least 90%, covers at least 95%, covers at least 99%, or completely covers) an orthographic projection of the respective anode on the planarization layer PLN.

The respective anode depicted in FIG. 8 shows only a main anode part of the respective anode. In alternative embodiments, the respective anode includes a main anode part, and an extension extending away from the main anode part and connected to an anode connecting pad; wherein the orthographic projection of the respective planarization enhancing block on the planarization layer PLN completely covers an orthographic projection of the main anode part on the planarization layer PLN. In some embodiments, the orthographic projection of the main anode part on the planarization layer PLN substantially overlaps with (e.g., no more than 100 nm distant from each other) an orthographic projection of a central region of the respective planarization enhancing block on the planarization layer PLN. Optionally, an orthographic projection of a peripheral region of the respective planarization enhancing block on the planarization layer PLN surrounds the orthographic projection of the main anode part on the planarization layer PLN. In one example, areas of the plurality of planarization enhancing blocks PEB differ from each other. For example, areas of planarization enhancing blocks corresponding to subpixels of a first color are different from areas of planarization enhancing blocks corresponding to subpixels of a second color, In an alternative example, areas of the plurality of planarization enhancing blocks PEB are substantially the same.

The inventors of the present disclosure discover that, by having the orthographic projection of the respective planarization enhancing block on the planarization layer PLN substantially covers the orthographic projection of at least the main anode part of the respective anode on the planarization layer PLN, the array substrate achieves an even surface of the planarization layer underneath the plurality of anodes AD. As a result, color separation issue can be alleviated.

In the array substrate depicted in FIG. 8, the respective planarization enhancing block has a round shape, e.g., a circular shape or an elliptical shape. In some embodiments, at least two planarization enhancing blocks of the plurality of planarization enhancing blocks PEB are spaced apart from each other. Optionally, the plurality of planarization enhancing blocks PEB are spaced apart from each other.

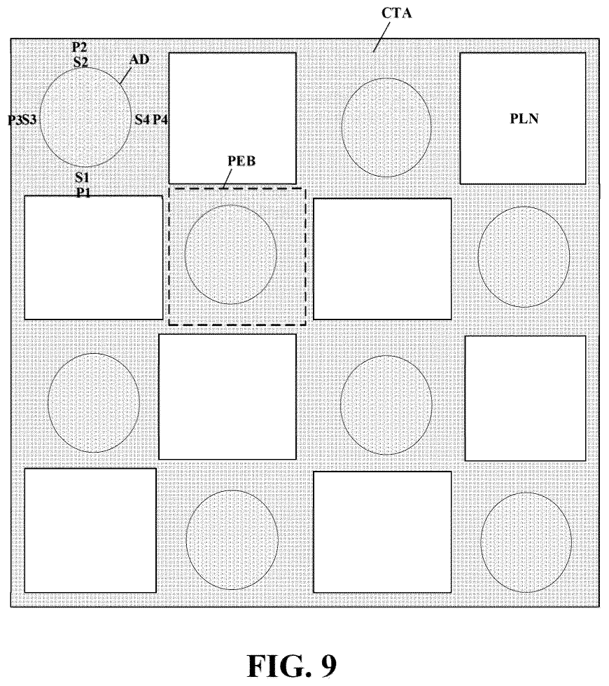

FIG. 9 illustrates a relative layout between an anode layer and a signal line layer closest to the anode in an array substrate in some embodiments according to the present disclosure. Referring to FIG. 9, the array substrate in some embodiments includes a signal line layer CTA closest to an anode, a planarization layer PLN on the signal line layer CTA closest to the anode, and a plurality of anodes AD on a side of the planarization layer PLN away from the signal line layer CTA closest to the anode. As shown in FIG. 9, the signal line layer CTA closest to the anode in some embodiments includes a plurality of planarization enhancing blocks PEB. A respective anode of the plurality of anodes AD is on a side of the planarization layer PLN away from a respective planarization enhancing block of the plurality of planarization enhancing blocks PEB. In some embodiments, an orthographic projection of the respective planarization enhancing block on the planarization layer PLN substantially covers (e.g., covers at least 80%, covers at least 85%, covers at least 90%, covers at least 95%, covers at least 99%, or completely covers) an orthographic projection of the respective anode on the planarization layer PLN.

The respective anode depicted in FIG. 9 shows only a main anode part of the respective anode. In alternative embodiments, the respective anode includes a main anode part, and an extension extending away from the main anode part and connected to an anode connecting pad; wherein the orthographic projection of the respective planarization enhancing block on the planarization layer PLN completely covers an orthographic projection of the main anode part on the planarization layer PLN. In some embodiments, the orthographic projection of the main anode part on the planarization layer PLN substantially overlaps with (e.g., no more than 100 nm distant from each other) an orthographic projection of a central region of the respective planarization enhancing block on the planarization layer PLN. Optionally, an orthographic projection of a peripheral region of the respective planarization enhancing block on the planarization layer PLN surrounds the orthographic projection of the main anode part on the planarization layer PLN.

The inventors of the present disclosure discover that, by having the orthographic projection of the respective planarization enhancing block on the planarization layer PLN substantially covers the orthographic projection of at least the main anode part of the respective anode on the planarization layer PLN, the array substrate achieves an even surface of the planarization layer underneath the plurality of anodes AD. As a result, color separation issue can be alleviated.

In some embodiments, the array substrate further includes a plurality of apertures AP extending through the signal line layer CTA closest to the anode. In some embodiments, a ratio of an area of a respective planarization enhancing block of the plurality of planarization enhancing blocks PEB to an area of a respective aperture of the plurality of apertures AP is in a range of 5:1 to 1:5, e.g., 5:1 to 4:1, 4:1 to 3:1, 3:1 to 2:1, 2:1 to 1:1, 1:1 to 1:2, 1:2 to 1:3, 1:3 to 1:4, or 1:4 to 1:5. In one example, the ratio of the area of the respective planarization enhancing block of the plurality of planarization enhancing blocks PEB to the area of the respective aperture of the plurality of apertures AP is in a range of 1.2:1 to 1:1.2.

In the array substrate depicted in FIG. 9, the respective planarization enhancing block has a rectangular shape or a square shape. In some embodiments, at least two planarization enhancing blocks of the plurality of planarization enhancing blocks PEB are parts of a unitary structure. Optionally, the plurality of planarization enhancing blocks PEB are parts of a unitary structure.

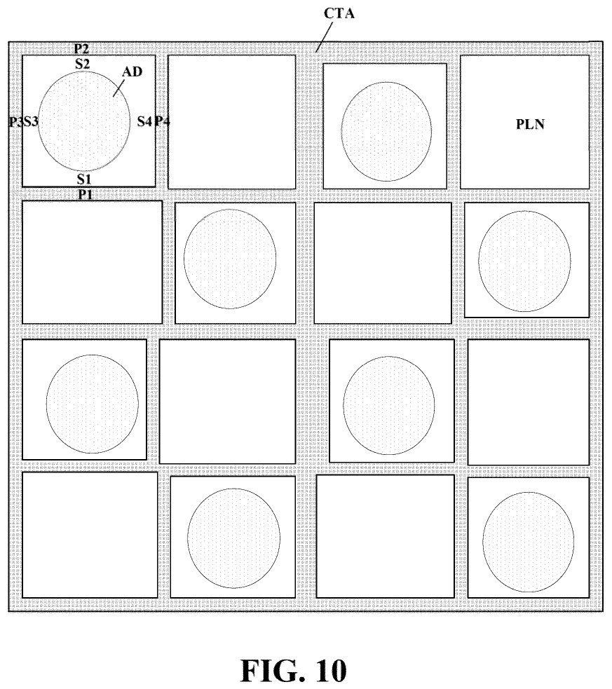

FIG. 10 illustrates a relative layout between an anode layer and a signal line layer closest to the anode in an array substrate in some embodiments according to the present disclosure. Referring to FIG. 10, in some embodiments, an orthographic projection of the respective anode on the planarization layer PLN is substantially non-overlapping (e.g., at least 80% non-overlapping, at least 90% non-overlapping, at least 95% non-overlapping, at least 99% non-overlapping, or completely non-overlapping) with an orthographic projection of the signal line layer CTA closest to the anode on the planarization layer PLN.

Referring to FIG. 10, in some embodiments, an orthographic projection of at least a main anode part of the respective anode on the planarization layer PLN is at least partially surrounded by an orthographic projection of portions of the signal line layer CTA closest to the anode on the planarization layer PLN. Optionally, the orthographic projection of at least the main anode part of the respective anode on the planarization layer PLN is at least partially surrounded by the orthographic projection of the portions of the signal line layer CTA closest to the anode on the planarization layer PLN in a substantially symmetrical (e.g., at least 80% symmetrical, at least 85% symmetrical, at least 90% symmetrical, at least 95% symmetrical, at least 98% symmetrical, at least 99% symmetrical, or completely symmetrical) manner. In some embodiments, an orthographic projection of a first portion P1 of the signal line layer CTA closest to the anode on the planarization layer PLN is on a first side S1 of the orthographic projection of at least the main anode part of the respective anode on the planarization layer PLN, an orthographic projection of a second portion P2 of the signal line layer CTA closest to the anode on the planarization layer PLN is on a second side S2 of the orthographic projection of at least the main anode part of the respective anode on the planarization layer PLN, the first side S1 being opposite to the second side S2. In some embodiments, the orthographic projection of the first portion PI of the signal line layer CTA closest to the anode on the planarization layer PLN and the orthographic projection of the second portion P2 of the signal line layer CTA closest to the anode on the planarization layer PLN have a substantial (e.g., at least 80% symmetrical, at least 85% symmetrical, at least 90% symmetrical, at least 95% symmetrical, at least 98% symmetrical, at least 99% symmetrical, or completely symmetrical) two-fold symmetry with respect to the orthographic projection of at least the main anode part of the respective anode on the planarization layer PLN (e.g., with respect to an orthographic projection of a central point of at least the main anode part of the respective anode on the planarization layer PLN).

In some embodiments, an orthographic projection of a third portion P3 of the signal line layer CTA closest to the anode on the planarization layer PLN is on a third side S3 of the orthographic projection of at least the main anode part of the respective anode on the planarization layer PLN, an orthographic projection of a fourth portion P4 of the signal line layer CTA closest to the anode on the planarization layer PLN is on a fourth side S4 of the orthographic projection of at least the main anode part of the respective anode on the planarization layer PLN, the third side S3 being opposite to the fourth side S4. In some embodiments, the orthographic projection of the third portion P3 of the signal line layer CTA closest to the anode on the planarization layer PLN and the orthographic projection of the fourth portion P4 of the signal line layer CTA closest to the anode on the planarization layer PLN have a substantial (e.g., at least 80% symmetrical, at least 85% symmetrical, at least 90% symmetrical, at least 95% symmetrical, at least 98% symmetrical, at least 99% symmetrical, or completely symmetrical) two-fold symmetry with respect to the orthographic projection of at least the main anode part of the respective anode on the planarization layer PLN (e.g., with respect to an orthographic projection of a central point of the respective anode on the planarization layer PLN).

The inventors of the present disclosure discover that, by having the orthographic projection of at least the main anode part of the respective anode on the planarization layer PLN at least partially surrounded by the orthographic projection of the portions of the signal line layer CTA closest to the anode on the planarization layer PLN in a substantially symmetrical manner, the array substrate achieves an even surface of the planarization layer underneath the plurality of anodes AD. As a result, color separation issue can be alleviated.

In some embodiments, the main anode part of the respective anode is spaced apart from the first portion P1 by a first shortest distance, spaced apart from the second portion P2 by a second shortest distance, spaced apart from the third portion P3 by a third shortest distance, and spaced apart from the fourth portion P4 by a fourth shortest distance. In one example, at least two of the first shortest distance, the second shortest distance, the third shortest distance, and the fourth shortest distance are different from each other, In an alternative example, the first shortest distance, the second shortest distance, the third shortest distance, and the fourth shortest distance are substantially the same.

The array substrates depicted in FIG. 8 and FIG. 9 differ from the array substrate depicted in FIG. 10 in that, in the array substrates depicted in FIG. 8 and FIG. 9, the orthographic projection of the respective anode on the planarization layer PLN at least partially overlaps with the orthographic projection of the signal line layer CTA closest to the anode on the planarization layer PLN. While in the array substrate depicted in FIG. 10, the orthographic projection of the respective anode on the planarization layer PLN is substantially non-overlapping with the orthographic projection of the signal line layer CTA closest to the anode on the planarization layer PLN. Nonetheless, the relative symmetrical layout depicted in FIG. 10 can be found in the array substrates depicted in FIG. 8 and FIG. 9.

Referring to FIG. 8 and FIG. 9, in some embodiments, an orthographic projection of at least the main anode part of the respective anode on the planarization layer PLN is at least partially surrounded by an orthographic projection of portions of the signal line layer CTA closest to the anode on the planarization layer PLN. Optionally, the orthographic projection of at least the main anode part of the respective anode on the planarization layer PLN is at least partially surrounded by the orthographic projection of the portions of the signal line layer CTA closest to the anode on the planarization layer PLN in a substantially symmetrical (e.g., at least 80% symmetrical, at least 85% symmetrical, at least 90% symmetrical, at least 95% symmetrical, at least 98% symmetrical, at least 99% symmetrical, or completely symmetrical) manner. In some embodiments, an orthographic projection of a first portion P1 of the signal line layer CTA closest to the anode on the planarization layer PLN is on a first side S1 of the orthographic projection of at least the main anode part of the respective anode on the planarization layer PLN, an orthographic projection of a second portion P2 of the signal line layer CTA closest to the anode on the planarization layer PLN is on a second side S2 of the orthographic projection of at least the main anode part of the respective anode on the planarization layer PLN, the first side S1 being opposite to the second side S2. In some embodiments, the orthographic projection of the first portion P1 of the signal line layer CTA closest to the anode on the planarization layer PLN and the orthographic projection of the second portion P2 of the signal line layer CTA closest to the anode on the planarization layer PLN have a substantial (e.g., at least 80% symmetrical, at least 85% symmetrical, at least 90% symmetrical, at least 95% symmetrical, at least 98% symmetrical, at least 99% symmetrical, or completely symmetrical) two-fold symmetry with respect to the orthographic projection of at least the main anode part of the respective anode on the planarization layer PLN (e.g., with respect to an orthographic projection of a central point of at least the main anode part of the respective anode on the planarization layer PLN).

In some embodiments, an orthographic projection of a third portion P3 of the signal line layer CTA closest to the anode on the planarization layer PLN is on a third side S3 of the orthographic projection of at least the main anode part of the respective anode on the planarization layer PLN, an orthographic projection of a fourth portion P4 of the signal line layer CTA closest to the anode on the planarization layer PLN is on a fourth side S4 of the orthographic projection of at least the main anode part of the respective anode on the planarization layer PLN, the third side S3 being opposite to the fourth side S4. In some embodiments, the orthographic projection of the third portion P3 of the signal line layer CTA closest to the anode on the planarization layer PLN and the orthographic projection of the fourth portion P4 of the signal line layer CTA closest to the anode on the planarization layer PLN have a substantial (e.g., at least 80% symmetrical, at least 85% symmetrical, at least 90% symmetrical, at least 95% symmetrical, at least 98% symmetrical, at least 99% symmetrical, or completely symmetrical) two-fold symmetry with respect to the orthographic projection of at least the main anode part of the respective anode on the planarization layer PLN (e.g., with respect to an orthographic projection of a central point of at least the main anode part of the respective anode on the planarization layer PLN).

Referring to FIG. 8, FIG. 9, and FIG. 10, in some embodiments, the orthographic projection of the first portion P1 of the signal line layer CTA closest to the anode on the planarization layer PLN and the orthographic projection of the second portion P2 of the signal line layer CTA closest to the anode on the planarization layer PLN have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane intersecting a central point of at least the main anode part of the respective anode and perpendicular to the main anode part of the respective anode. In some embodiments, the orthographic projection of the third portion P3 of the signal line layer CTA closest to the anode on the planarization layer PLN and the orthographic projection of the fourth portion P4 of the signal line layer CTA closest to the anode on the planarization layer PLN have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane intersecting a central point of at least the main anode part of the respective anode and perpendicular to the main anode part of the respective anode.

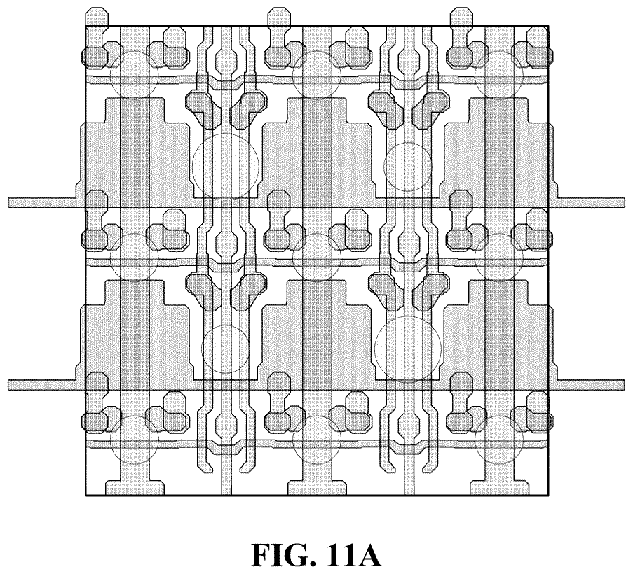

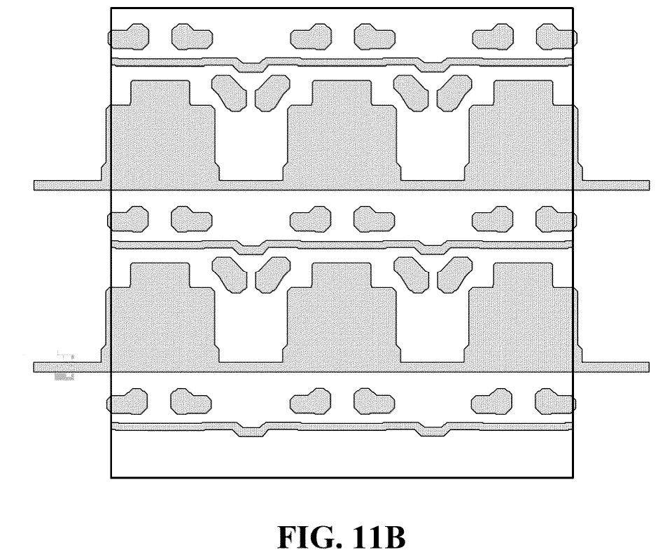

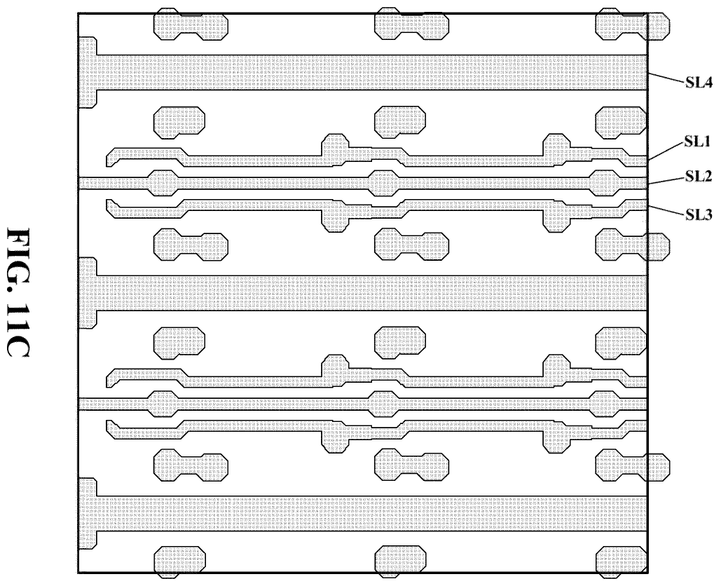

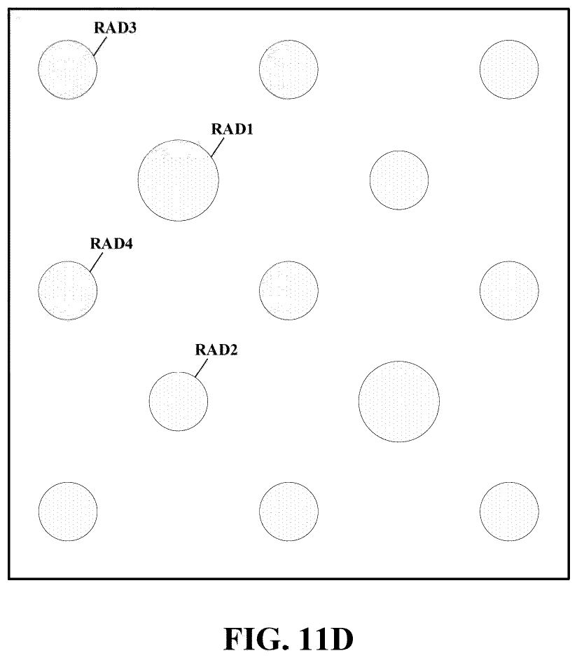

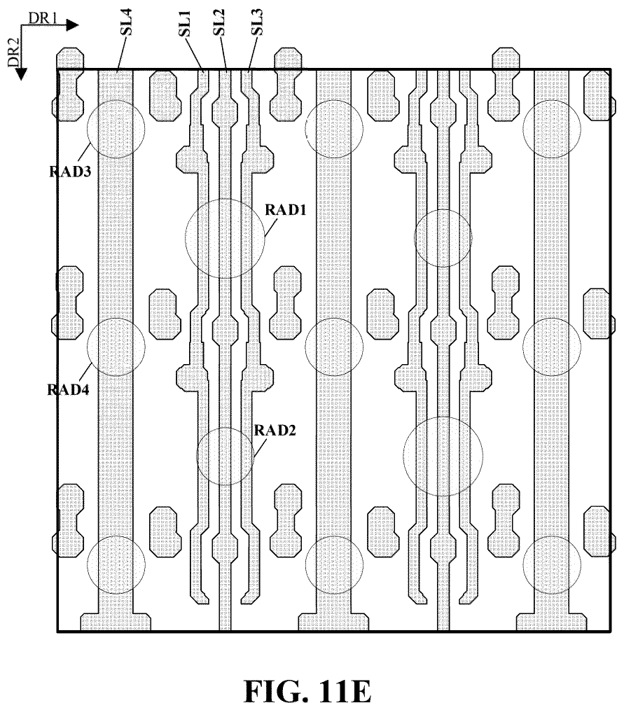

FIG. 11A illustrates the structures of a second signal line layer, a third signal line layer, and an anode layer in an array substrate in some embodiments according to the present disclosure. FIG. 11B illustrates the structure of a second signal line layer in an array substrate in some embodiments according to the present disclosure. FIG. 11C illustrates the structure of a third signal line layer in an array substrate in some embodiments according to the present disclosure. FIG. 11D illustrates the structure of an anode layer in an array substrate in some embodiments according to the present disclosure, FIG. 11E illustrates the structures of a third signal line layer and an anode layer in an array substrate in some embodiments according to the present disclosure. In some embodiments, the anode layer is on a side of the third signal line layer away from the second signal line layer. Optionally, the third signal line layer is the signal line layer closest to the anode layer.

Referring to FIG. 11A to FIG. 11E, the anode layer in some embodiments includes a first respective anode RAD1, a second respective anode RAD2, a third respective anode RAD3, and a fourth respective anode RAD4. In one example, the first respective anode RAD1 is an anode for a subpixel of a first color (e.g., a red subpixel), the second respective anode RAD2 is an anode for a subpixel of a second color (e.g., a blue subpixel), and the third respective anode RAD3 and the fourth respective anode RAD4 are anodes for two subpixels of a third color (e.g., two green subpixels). In some embodiments, an array of the plurality of subpixels in the array substrate includes a R-G-B-G format repeating array, in which R stands for the red subpixel, B stands for the blue subpixel, and G stands for the green subpixel In some embodiments, an orthographic projection of the first respective anode RAD1 on a base substrate at least partially overlaps with each of orthographic projections of multiple signal lines on the base substrate. In some embodiments, the multiple signal lines cross over the first respective anode RAD1, respectively. In some embodiments, the multiple signal lines are substantially evenly distributed along a first direction DR1 with respect to the first respective anode RAD1. For example, portions of the multiple signal lines, in a region crossing over the first respective anode RAD1, are equi-spaced. In another example, portions of the multiple signal lines, in a region crossing over the first respective anode RAD1, have a substantial (e.g., at least 80%, at least 85%, at least 90%, at least 95%, or at least 99%) mirror symmetry with respect to a plane perpendicular to the first respective anode RAD1, intersecting the first respective anode RAD1, and substantially parallel to a second direction DR2. Optionally, the second direction DR2 is an extension direction of the first signal line SL1, the second signal line SL2, and the third signal line SL3. The inventors of the present disclosure discover that, by having the intricate structure of anodes and signal lines according to the present disclosure, an even surface of the planarization layer underneath the first respective anode RAD1 can be achieved. As a result, color separation issue can be alleviated.

In some embodiments, the third signal line layer includes a first signal line SL1, a second signal line SL2, and a third signal line SL3. In some embodiments, an orthographic projection of the first respective anode RAD1 on a base substrate at least partially overlaps with each of orthographic projections of the first signal line SL1, the second signal line SL2, and the third signal line SL3 on the base substrate. In some embodiments, the first signal line SL1, the second signal line SL2, and the third signal line SL3 cross over the first respective anode RAD1, respectively. In some embodiments, the first signal line SL1, the second signal line SL2, and the third signal line SL3 are substantially evenly distributed along a first direction DR1 with respect to the first respective anode RAD1. For example, portions of the first signal line SL1, the second signal line SL2, and the third signal line SL3, in a region crossing over the first respective anode RAD1, are equi-spaced. In another example, portions of the first signal line SL1, the second signal line SL2, and the third signal line SL3, in a region crossing over the first respective anode RAD1, have a substantial (e.g., at least 80%, at least 85%, at least 90%, at least 95%, or at least 99%) mirror symmetry with respect to a plane perpendicular to the first respective anode RAD1, intersecting the first respective anode RAD1, and substantially parallel to a second direction DR2. Optionally, the second direction DR2 is an extension direction of the first signal line SL1, the second signal line SL2, and the third signal line SL3.

In some embodiments, an orthographic projection of the second respective anode RAD2 on a base substrate at least partially overlaps with each of orthographic projections of multiple signal lines on the base substrate. In some embodiments, the multiple signal lines cross over the second respective anode RAD2, respectively. In some embodiments, the multiple signal lines are substantially evenly distributed along a first direction DR1 with respect to the second respective anode RAD2. For example, portions of the multiple signal lines, in a region crossing over the second respective anode RAD2, are equi-spaced. In another example, portions of the multiple signal lines, in a region crossing over the second respective anode RAD2, have a substantial (e.g., at least 80%, at least 85%, at least 90%, at least 95%, or at least 99%) mirror symmetry with respect to a plane perpendicular to the second respective anode RAD2, intersecting the second respective anode RAD2, and substantially parallel to a second direction DR2. Optionally, the second direction DR2 is an extension direction of the first signal line SL1, the second signal line SL2, and the third signal line SL3. The inventors of the present disclosure discover that, by having the intricate structure of anodes and signal lines according to the present disclosure, an even surface of the planarization layer underneath the second respective anode RAD2 can be achieved. As a result, color separation issue can be alleviated.

In some embodiments, the third signal line layer includes a first signal line SL1, a second signal line SL2, and a third signal line SL3. In some embodiments, an orthographic projection of the second respective anode RAD2 on a base substrate at least partially overlaps with each of orthographic projections of the first signal line SL1, the second signal line SL2, and the third signal line SL3 on the base substrate. In some embodiments, the first signal line SL1, the second signal line SL2, and the third signal line SL3 cross over the second respective anode RAD2, respectively. In some embodiments, the first signal line SL1, the second signal line SL2, and the third signal line SL3 are substantially evenly distributed along a first direction DR1 with respect to the second respective anode RAD2. For example, portions of the first signal line SL1, the second signal line SL2, and the third signal line SL3, in a region crossing over the second respective anode RAD2, are equi-spaced. In another example, portions of the first signal line SL1, the second signal line SL2, and the third signal line SL3, in a region crossing over the second respective anode RAD2, have a substantial (e.g., at least 80%, at least 85%, at least 90%, at least 95%, or at least 99%) mirror symmetry with respect to a plane perpendicular to the second respective anode RAD2, intersecting the second respective anode RAD2, and substantially parallel to a second direction DR2. Optionally, the second direction DR2 is an extension direction of the first signal line SL1, the second signal line SL2, and the third signal line SL3.

In some embodiments, the third signal line layer further includes a fourth signal line SL4. In some embodiments, an orthographic projection of the third respective anode RAD3 on a base substrate at least partially overlaps with an orthographic projection of the fourth signal line SL4 on the base substrate. In some embodiments, the fourth signal line SL4 crosses over the third respective anode RAD3. In some embodiments, a portion of the fourth signal line SL4, in a region crossing over the third respective anode RAD3, have a substantial (e.g., at least 80%, at least 85%, at least 90%, at least 95%, or at least 99%) mirror symmetry with respect to a plane perpendicular to the third respective anode RAD3, intersecting the third respective anode RAD3, and substantially parallel to a second direction DR2. Optionally, the second direction DR2 is an extension direction of the fourth signal line SL4.

In some embodiments, an orthographic projection of the fourth respective anode RAD4 on a base substrate at least partially overlaps with an orthographic projection of the fourth signal line SL4 on the base substrate. In some embodiments, the fourth signal line SL4 crosses over the fourth respective anode RAD4. In some embodiments, a portion of the fourth signal line SL4, in a region crossing over the fourth respective anode RAD4, have a substantial (e.g., at least 80%, at least 85%, at least 90%, at least 95%, or at least 99%) mirror symmetry with respect to a plane perpendicular to the fourth respective anode RAD4, intersecting the fourth respective anode RAD4, and substantially parallel to a second direction DR2. Optionally, the second direction DR2 is an extension direction of the fourth signal line SL4.

In some embodiments, the first signal line SL1 and the third signal line SL3 are two adjacent data lines of a plurality of data lines configured to provide data signals to two adjacent columns of subpixels, respectively. Optionally, the second signal line SL2 is a low voltage signal line configured to provide a low voltage signal to a cathode of a light emitting element. Optionally, the fourth signal line SL4 is a voltage supply line configured to provide a voltage supply signal to a pixel driving circuit, e.g., to a first electrode of a light emitting element in the pixel driving circuit. In some embodiments, the first signal line SL1 and the third signal line SL3 are spaced apart from each other by a distance less than a width of a subpixel.

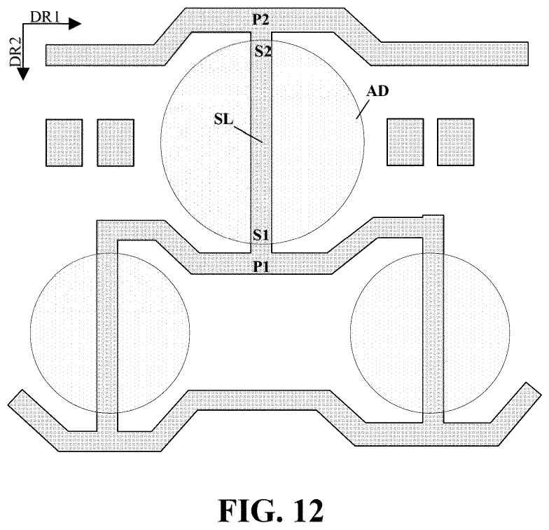

FIG. 12 illustrates a relative layout between an anode layer and a signal line layer closest to the anode in an array substrate in some embodiments according to the present disclosure. Referring to FIG. 12, the anode layer includes a plurality of anodes AD, the signal line layer closest to the anode includes a signal line SL. In some embodiments, an orthographic projection of a respective anode of the plurality of anodes AD on a base substrate at least partially overlaps with an orthographic projection of the signal line SL on the base substrate. In some embodiments, the signal line SL crosses over the respective anode, In some embodiments, a portion of the signal line SL, in a region crossing over the respective anode, have a substantial (e.g., at least 80%, at least 85%, at least 90%, at least 95%, or at least 99%) mirror symmetry with respect to a plane perpendicular to the respective anode, intersecting the respective anode, and substantially parallel to a second direction DR2. Optionally, the second direction DR2 is an extension direction of the signal line SL.

In some embodiments, the signal line layer closest to the anode further includes a first portion P1 and a second portion P2. In some embodiments, an orthographic projection of the first portion P1 of the signal line layer closest to the anode on a base substrate is on a first side S1 of the orthographic projection of at least the main anode part of an individual anode on the base substrate, an orthographic projection of a second portion P2 of the signal line layer closest to the anode on the base substrate is on a second side S2 of the orthographic projection of at least the main anode part of the individual anode on the base substrate, the first side S1 being opposite to the second side S2. In some embodiments, the orthographic projection of the first portion P1 of the signal line layer closest to the anode on the base substrate and the orthographic projection of the second portion P2 of the signal line layer closest to the anode on the base substrate have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the individual anode, intersecting the individual anode, and substantially parallel to a second direction DR2. Optionally, the second direction DR2 is an extension direction of the signal line SL.

In some embodiments, each of the anode layer and the signal line layer closest to the anode has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the individual anode, intersecting the individual anode, and substantially parallel to a second direction DR2, Optionally, the second direction DR2 is an extension direction of the signal line SL. In some embodiments, the plane intersects the signal line SL. In one example, a central line of the signal line SL substantially overlaps with the plane.

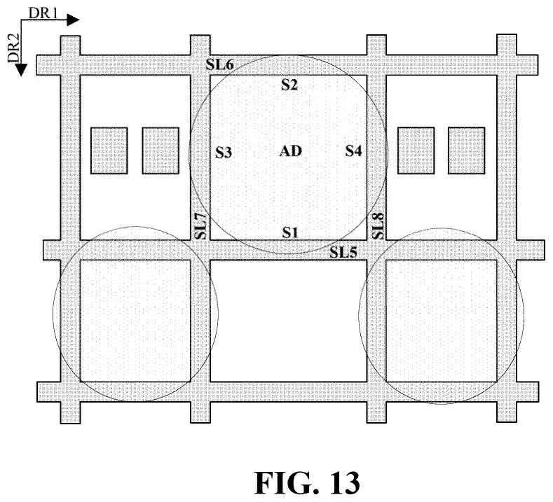

FIG. 13 illustrates a relative layout between an anode layer and a signal line layer closest to the anode in an array substrate in some embodiments according to the present disclosure, Referring to FIG. 13, the anode layer includes a plurality of anodes AD, the signal line layer closest to the anode includes a fifth signal line SL5, a sixth signal line SL6, a seventh signal line SL7, and an eighth signal line SL8. In some embodiments, an orthographic projection of a respective anode of the plurality of anodes AD on a base substrate at least partially overlaps with an orthographic projection of the fifth signal line SL5 on the base substrate, at least partially overlaps with an orthographic projection of the sixth signal line SL6 on the base substrate, at least partially overlaps with an orthographic projection of the seventh signal line SL7 on the base substrate, and at least partially overlaps with an orthographic projection of the eighth signal line SL8 on the base substrate. In some embodiments, the fifth signal line SL5 is on a first side S1 of a central point of the respective anode, the sixth signal line SL6 is on a second side S2 of the central point of the respective anode, the seventh signal line SL7 is on a third side S3 of the central point of the respective anode, and the eighth signal line SL8 is on a fourth side S4 of the central point of the respective anode. Optionally, the first side S1 and the second side S2 are opposite to each other, and the third side S3 and the fourth side S4 are opposite to each other.

In some embodiments, the orthographic projection of the fifth signal line SL5 of the signal line layer closest to the anode on a base substrate and the orthographic projection of the sixth signal line SL6 of the signal line layer closest to the anode on the base substrate have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane intersecting a central point of at least the main anode part of the respective anode and perpendicular to the main anode part of the respective anode, for example, with respect to a plane intersecting a central point of at least the main anode part of the respective anode, perpendicular to the main anode part of the respective anode, and substantially parallel to a second direction DR2. In some embodiments, the orthographic projection of the seventh signal line SL7 of the signal line layer closest to the anode on the base substrate and the orthographic projection of the eighth signal line SL8 of the signal line layer closest to the anode on the base substrate have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane intersecting a central point of at least the main anode part of the respective anode and perpendicular to the main anode part of the respective anode, for example, with respect to a plane intersecting a central point of at least the main anode part of the respective anode, perpendicular to the main anode part of the respective anode, and substantially parallel to a first direction DR1.

In some embodiments, each of the anode layer and the signal line layer closest to the anode has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to an individual anode, intersecting the individual anode, and substantially parallel to a second direction DR2.

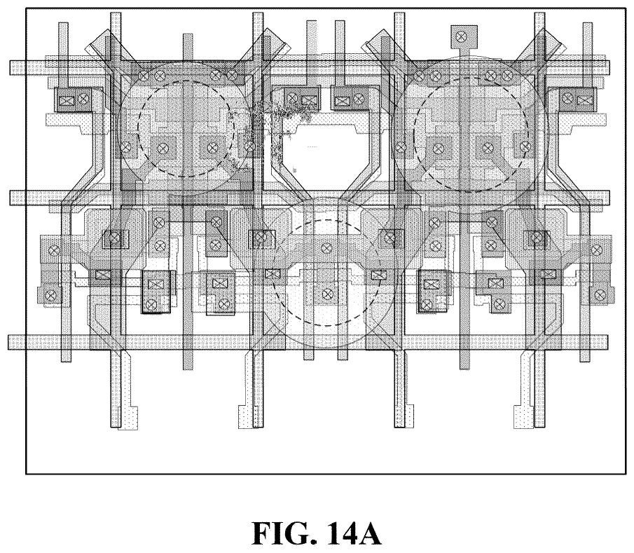

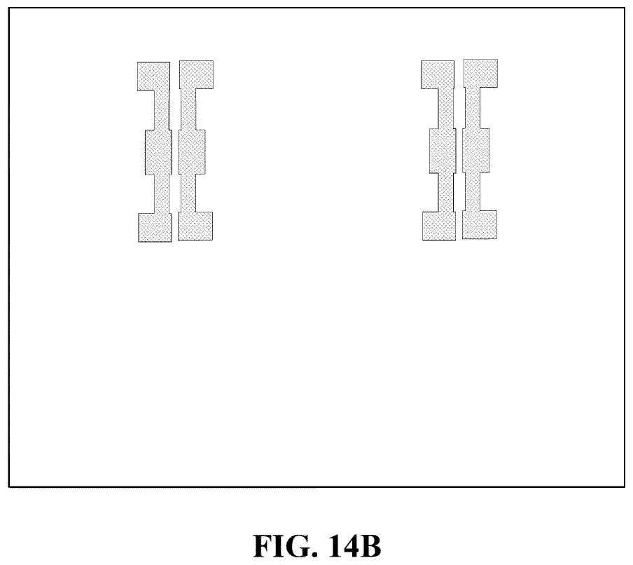

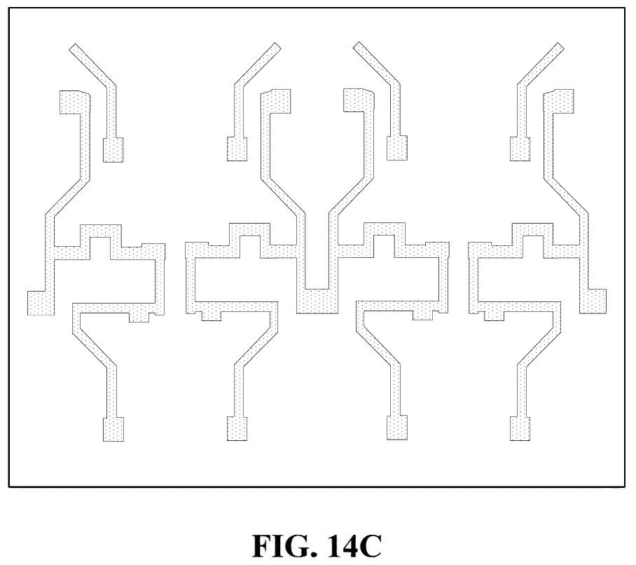

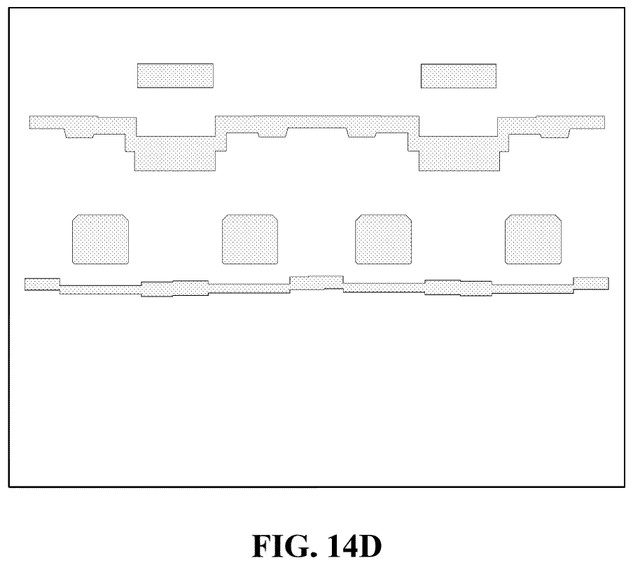

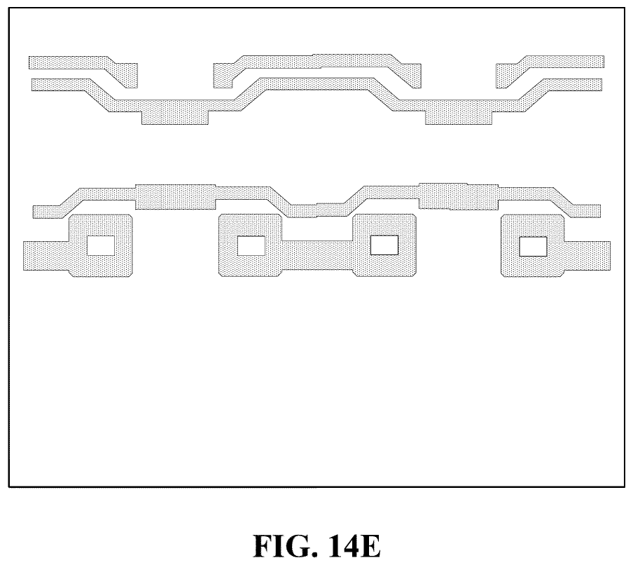

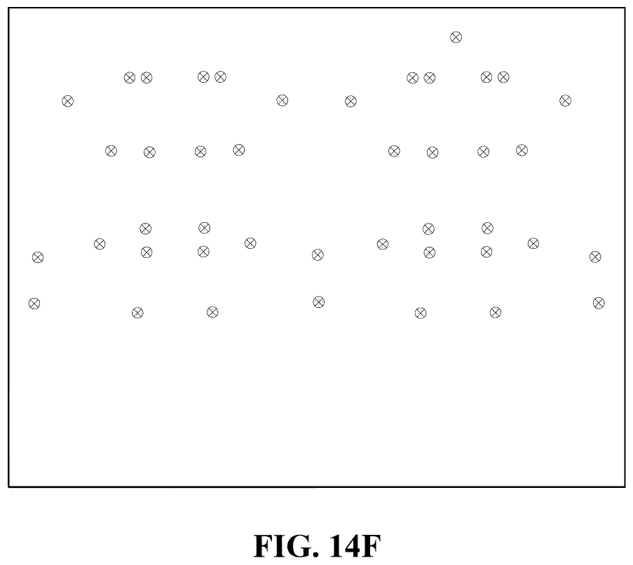

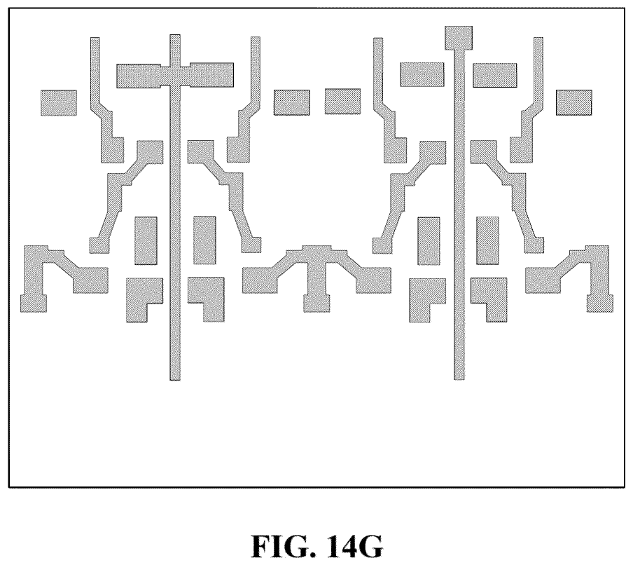

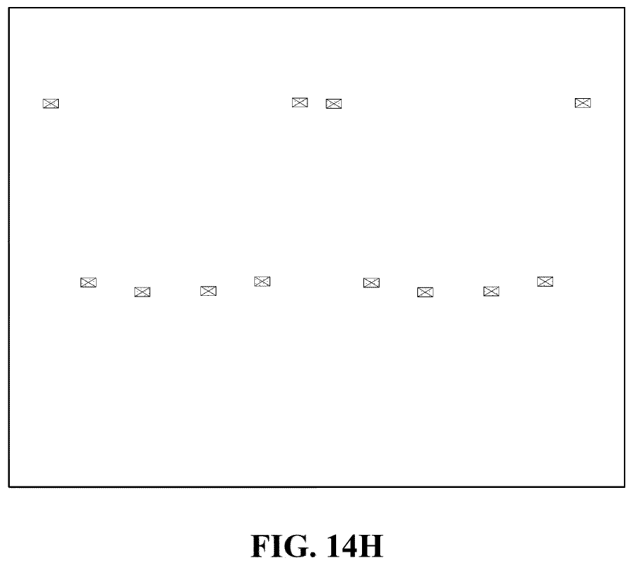

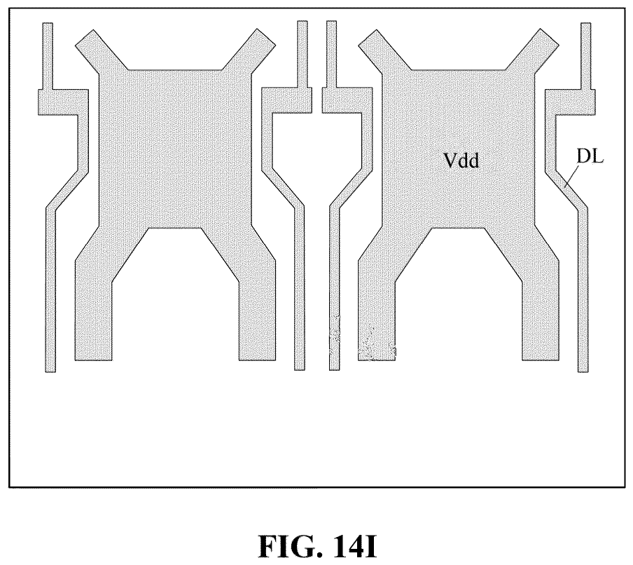

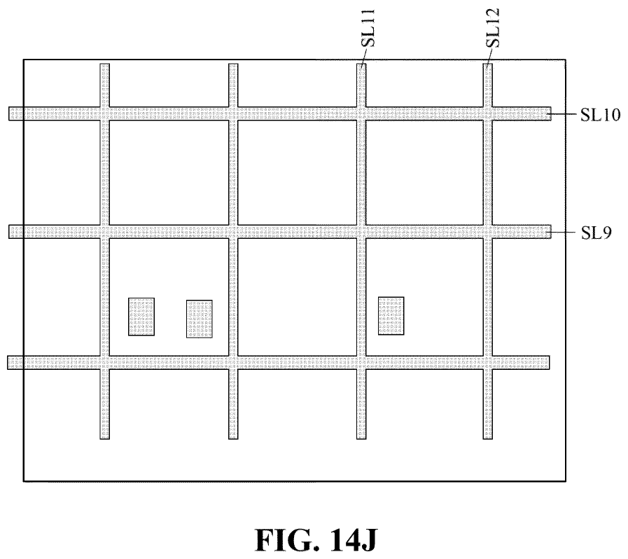

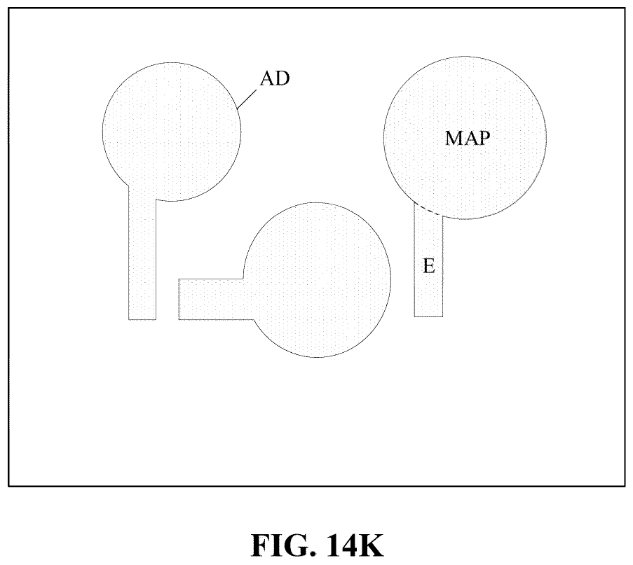

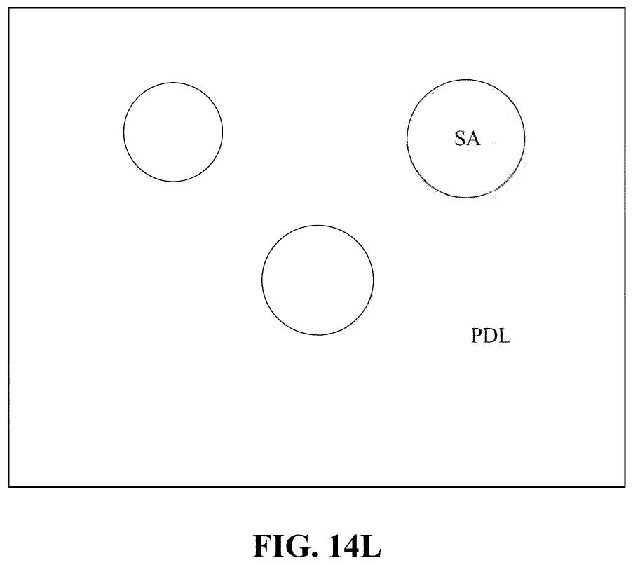

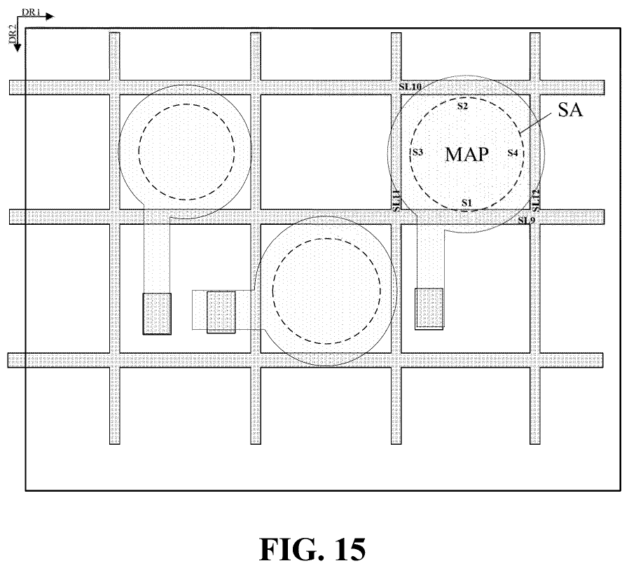

FIG. 14A is a diagram illustrating the structure of an array substrate in some embodiments according to the present disclosure. FIG. 14B is a diagram illustrating the structure of a light shielding layer in the array substrate depicted in FIG. 14A, FIG. 14C is a diagram illustrating the structure of a first semiconductor material layer in the array substrate depicted in FIG. 14A. FIG. 14D is a diagram illustrating the structure of a first gate metal layer in the array substrate depicted in FIG. 14A. FIG. 14E is a diagram illustrating the structure of a second gate metal layer in the array substrate depicted in FIG. 14A. FIG. 14F is a diagram illustrating vias extending through an insulating layer in the array substrate depicted in FIG. 14A. FIG. 14G is a diagram illustrating the structure of a first signal line layer in the array substrate depicted in FIG. 14A. FIG. 14H is a diagram illustrating vias extending through a first planarization layer in the array substrate depicted in FIG. 14A. FIG. 14I is a diagram illustrating the structure of a second signal line layer in the array substrate depicted in FIG. 14A. FIG. 14J is a diagram illustrating the structure of a third signal line layer in the array substrate depicted in FIG. 14A, FIG. 14K is a diagram illustrating the structure of an anode layer in the array substrate depicted in FIG. 14A. FIG. 14L is a diagram illustrating the structure of a pixel definition layer in the array substrate depicted in FIG. 14A, FIG. 15 is a diagram illustrating the structures of a third signal line layer and an anode layer in the array substrate depicted in FIG. 14A.

Referring to FIG. 14A to FIG. 14L, and FIG. 15, a respective anode of the plurality of anodes AD in some embodiments includes a main anode part MAP and an extension E extending away from the main anode part MAP, The extension E connects the main anode part MAP with a corresponding anode connecting pad. The pixel definition layer PDL defines a plurality of subpixel apertures SA, through which the main anode part of the respective anode is in contact with organic materials.

In some embodiments, the anode layer includes a plurality of anodes AD, the third signal line layer includes a ninth signal line SL9, a tenth signal line SL10, an eleventh signal line SL11, and a twelfth signal line SL12. In some embodiments, an orthographic projection of a main anode part MAP of a respective anode of the plurality of anodes AD on a base substrate at least partially overlaps with an orthographic projection of the ninth signal line SL9 on the base substrate, at least partially overlaps with an orthographic projection of the tenth signal line SL10 on the base substrate, at least partially overlaps with an orthographic projection of the eleventh signal line SL11 on the base substrate, and at least partially overlaps with an orthographic projection of the twelfth signal line SL12 on the base substrate. In some embodiments, the ninth signal line SL9 is on a first side S1 of a central point of the main anode part MAP of the respective anode, the tenth signal line SL10 is on a second side S2 of the central point of the main anode part MAP of the respective anode, the eleventh signal line SL11 is on a third side S3 of the central point of the main anode part MAP of the respective anode, and the twelfth signal line SL12 is on a fourth side S4 of the central point of the main anode part MAP of the respective anode. Optionally, the first side S1 and the second side S2 are opposite to each other, and the third side S3 and the fourth side S4 are opposite to each other.

In some embodiments, the orthographic projection of the ninth signal line SL9 of the third signal line layer on a base substrate and the orthographic projection of the tenth signal line SL10 of the third signal line layer on the base substrate have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane intersecting a central point of at least the main anode part MAP of the respective anode and perpendicular to the main anode part MAP of the respective anode, for example, with respect to a plane intersecting a central point of at least the main anode part MAP of the respective anode, perpendicular to the main anode part MAP of the respective anode, and substantially parallel to a second direction DR2. In some embodiments, the orthographic projection of the eleventh signal line SL11 of the third signal line layer on the base substrate and the orthographic projection of the twelfth signal line SL12 of the third signal line layer on the base substrate have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane intersecting a central point of at least the main anode part MAP of the respective anode and perpendicular to the main anode part MAP of the respective anode, for example, with respect to a plane intersecting a central point of at least the main anode part MAP of the respective anode, perpendicular to the main anode part MAP of the respective anode, and substantially parallel to a first direction DR1.

In some embodiments, each of the anode layer and the third signal line layer has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to an individual anode, intersecting the individual anode, and substantially parallel to a second direction DR2.

In some embodiments, the ninth signal line SL9, the tenth signal line SL10, the eleventh signal line SL11, and the twelfth signal line SL12 are signal lines in an interconnected voltage supply network in the third signal line layer. The second signal line layer may include a plurality of voltage supply lines and a plurality of data lines. A respective voltage supply line Vdd of the plurality of voltage supply lines and a respective data line DL of the plurality of data lines are denoted in FIG. 14I.

In some embodiments, the interconnected voltage supply network in the third signal line layer has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to an individual anode, intersecting the individual anode, and substantially parallel to a second direction DR2.

The inventors of the present disclosure discover that, by having the intricate structure depicted in FIG. 14A to FIG. 14L, the array substrate achieves an even surface of the planarization layer underneath the plurality of anodes AD. As a result, color separation issue can be alleviated.

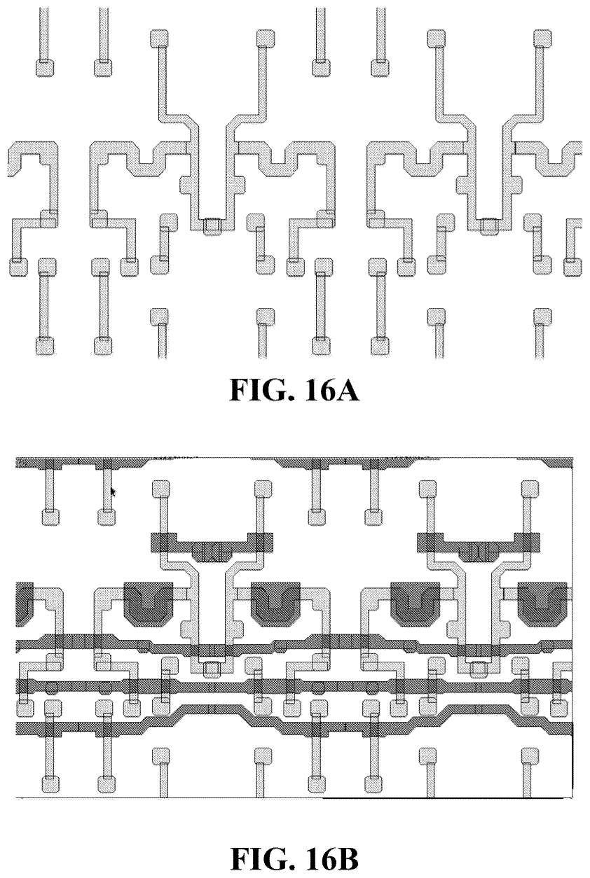

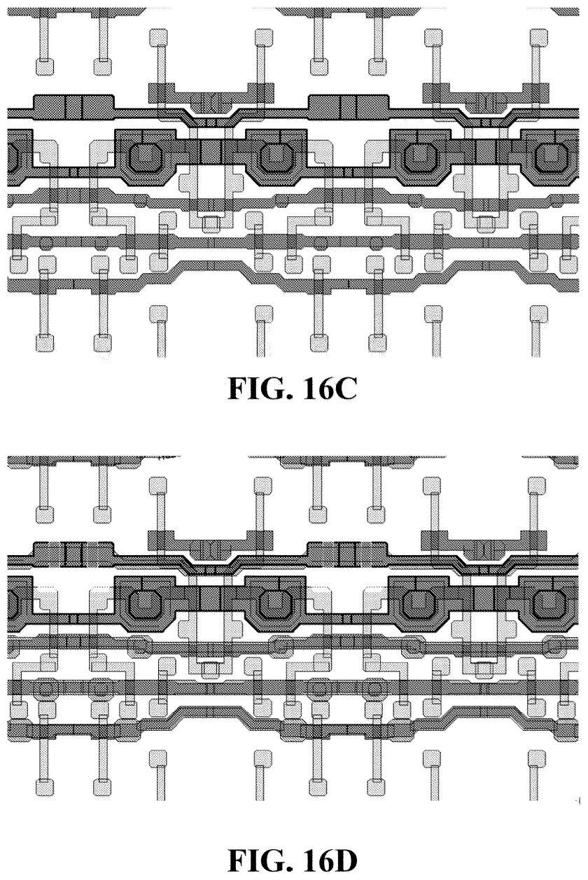

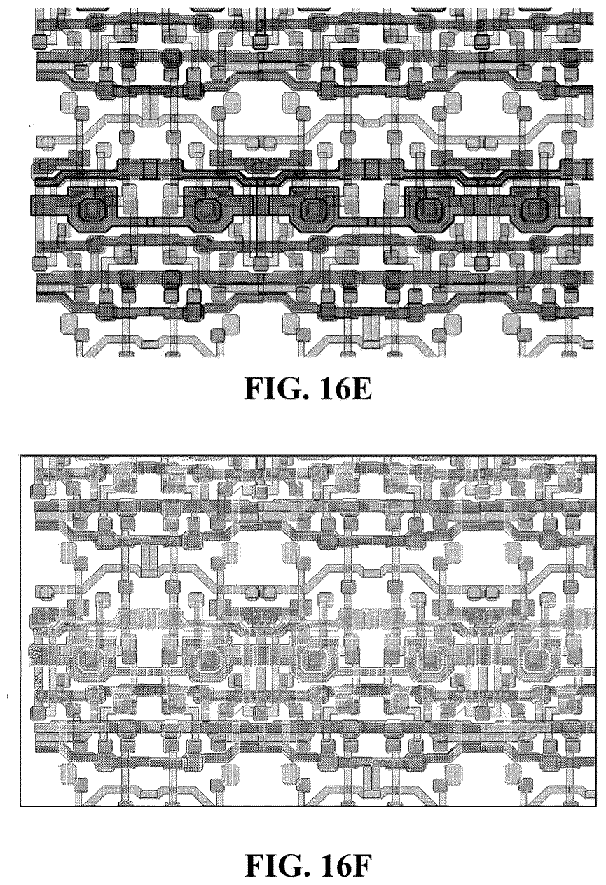

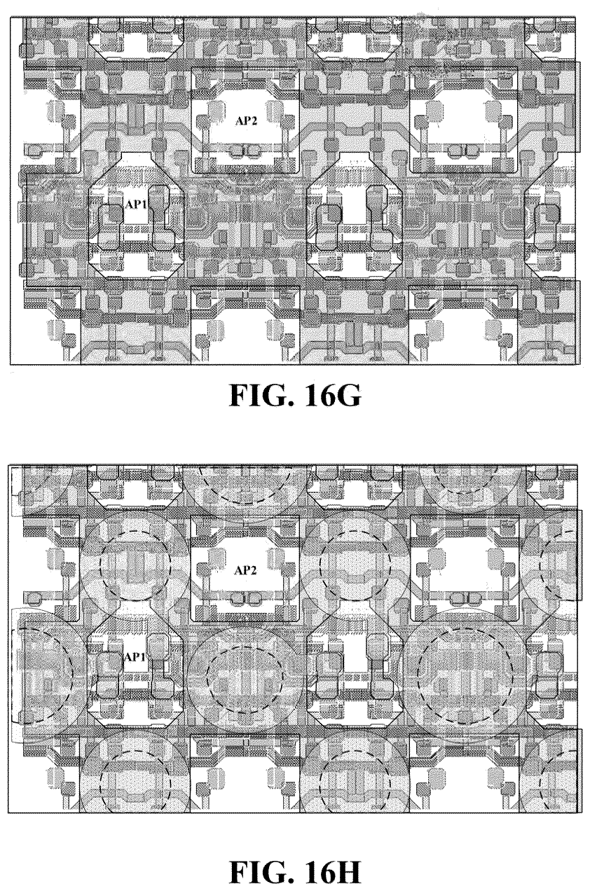

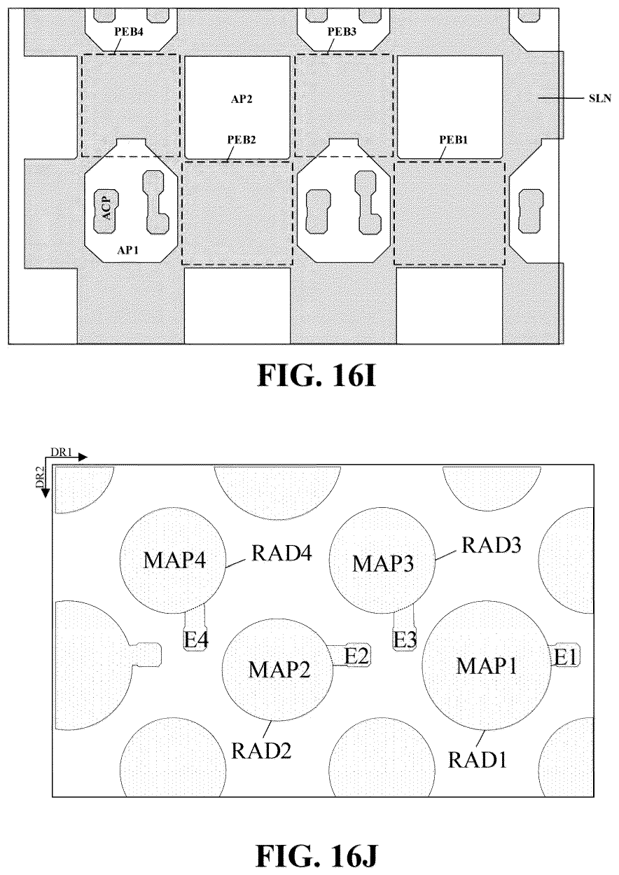

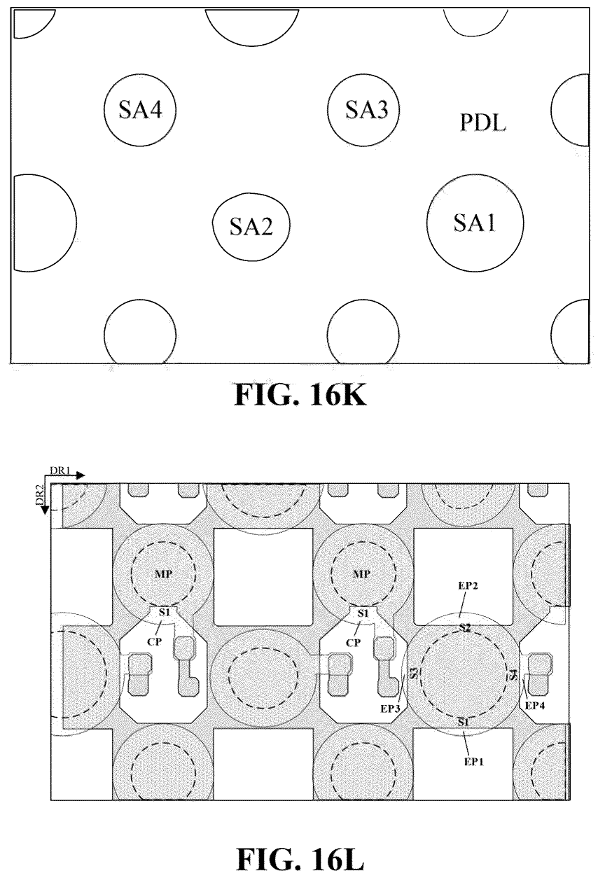

FIG. 16A is a diagram illustrating the structure of a first semiconductor material layer in an array substrate in some embodiments according to the present disclosure. FIG. 16B is a diagram illustrating the structures of a first semiconductor material layer and a first gate metal layer in an array substrate in some embodiments according to the present disclosure, FIG. 16C is a diagram illustrating the structures of a first semiconductor material layer, a first gate metal layer, and a second gate metal layer in an array substrate in some embodiments according to the present disclosure. FIG. 16D is a diagram illustrating the structures of a first semiconductor material layer, a first gate metal layer, a second gate metal layer, a second semiconductor material layer, and a third gate metal layer in an array substrate in some embodiments according to the present disclosure. FIG. 16E is a diagram illustrating the structures of a first semiconductor material layer, a first gate metal layer, a second gate metal layer, a second semiconductor material layer, a third gate metal layer, an inter-layer dielectric layer, and a first signal line layer in an array substrate in some embodiments according to the present disclosure. FIG. 16F is a diagram illustrating the structures of a first semiconductor material layer, a first gate metal layer, a second gate metal layer, a second semiconductor material layer, a third gate metal layer, an inter-layer dielectric layer, a first signal line layer, a passivation layer, a first planarization layer, and a second signal line layer in an array substrate in some embodiments according to the present disclosure. FIG. 16G is a diagram illustrating the structures of a first semiconductor material layer, a first gate metal layer, a second gate metal layer, a second semiconductor material layer, a third gate metal layer, an inter-layer dielectric layer, a first signal line layer, a passivation layer, a first planarization layer, a second signal line layer, a second planarization layer, and a third signal line layer in an array substrate in some embodiments according to the present disclosure. FIG. 16H is a diagram illustrating the structures of a first semiconductor material layer, a first gate metal layer, a second gate metal layer, a second semiconductor material layer, a third gate metal layer, an inter-layer dielectric layer, a first signal line layer, a passivation layer, a first planarization layer, a second signal line layer, a second planarization layer, a third signal line layer, a third planarization layer, an anode layer, and a pixel definition layer in an array substrate in some embodiments according to the present disclosure. FIG. 16I is a diagram illustrating the structure of a third signal line layer in an array substrate in some embodiments according to the present disclosure. FIG. 16J is a diagram illustrating the structure of an anode layer in an array substrate in some embodiments according to the present disclosure. FIG. 16K is a diagram illustrating the structure of a pixel definition layer in an array substrate in some embodiments according to the present disclosure. FIG. 16L is a diagram illustrating the structures of a third planarization layer and an anode layer in an array substrate in some embodiments according to the present disclosure.

Referring to FIG. 16G, FIG. 16H, and FIG. 16I, the array substrate in some embodiments includes a plurality of first apertures AP1 and a plurality of second apertures AP2 extending through the third signal line layer. In one example, the third signal line layer includes an interconnected signal line network SLN, as shown in FIG. 16L In some embodiments, the third signal line layer further includes one or more anode connecting pads ACP in a respective first aperture of the plurality of first apertures AP1. A respective anode connecting pad of the one or more anode connecting pads ACP is connected to a respective anode. The plurality of second apertures AP2 are substantially transparent regions, allowing accessories such as photosensors to be installed therein.

Referring to FIG. 16J, the anode layer in some embodiments includes a first respective anode RAD1, a second respective anode RAD2, a third respective anode RAD3, and a fourth respective anode RAD4. In one example, the first respective anode RAD1 is an anode for a subpixel of a first color (e.g., a red subpixel), the second respective anode RAD2 is an anode for a subpixel of a second color (e.g., a blue subpixel), and the third respective anode RAD3 and the fourth respective anode RAD4 are anodes for two subpixels of a third color (e.g., two green subpixels). In some embodiments, an array of the plurality of subpixels in the array substrate includes a R-G-B-G format repeating array, in which R stands for the red subpixel, B stands for the blue subpixel, and G stands for the green subpixel.

In some embodiments, the first respective anode RAD1 includes a first main anode part MAP1 and a first extension E1 extending away from the first main anode part MAP1. The first extension E1 connects the first main anode part MAP1 with a first corresponding anode connecting pad. In some embodiments, the second respective anode RAD2 includes a second main anode part MAP2 and a second extension E2 extending away from the second main anode part MAP2. The second extension E2 connects the second main anode part MAP2 with a second corresponding anode connecting pad. In some embodiments, the third respective anode RAD3 includes a third main anode part MAP3 and a third extension E3 extending away from the third main anode part MAP3. The third extension E3 connects the third main anode part MAP3 with a third corresponding anode connecting pad. In some embodiments, the fourth respective anode RAD4 includes a fourth main anode part MAP4 and a fourth extension E4 extending away from the fourth main anode part MAP4. The fourth extension E4 connects the fourth main anode part MAP4 with a fourth corresponding anode connecting pad.

Optionally, the first extension E1 extends away from the first main anode part MAP1 along a direction substantially parallel to the first direction DR1. Optionally, the second extension E2 extends away from the second main anode part MAP2 along a direction substantially parallel to the first direction DR1. Optionally, the third extension E3 extends away from the third main anode part MAP3 along a direction substantially parallel to the second direction DR2. Optionally, the fourth extension E4 extends away from the fourth main anode part MAP4 along a direction substantially parallel to the second direction DR2.

Referring to FIG. 16I to FIG. 16L, the array substrate in some embodiments includes a plurality of subpixel apertures extending through the pixel definition layer PDL. A main anode part of a respective anode is in contact with organic materials through a respective subpixel aperture of the plurality of subpixel apertures. The plurality of subpixel apertures includes a first subpixel aperture SA1, a second subpixel aperture SA2, a third subpixel aperture SA3, and a fourth subpixel aperture SA4. The first main anode part MAP1 is in contact with organic materials through the first subpixel aperture SA1. The second main anode part MAP2 is in contact with organic materials through the second subpixel aperture SA2, The third main anode part MAP3 is in contact with organic materials through the third subpixel aperture SA3. The fourth main anode part MAP4 is in contact with organic materials through the fourth subpixel aperture SA4.

Referring to FIG. 16I to FIG. 16L, the third signal line layer in some embodiments includes a plurality of planarization enhancing blocks (e.g., a first planarization enhancing block PEB1, a second planarization enhancing block PEB2, a third planarization enhancing block PEB3, and a fourth planarization enhancing block PEB4). In some embodiments, an orthographic projection of the respective planarization enhancing block on a base substrate substantially covers (e.g., covers at least 80%, covers at least 85%, covers at least 90%, covers at least 95%, covers at least 99%, or completely covers) an orthographic projection of at least a main anode part of the respective anode on the base substrate. In some embodiments, an orthographic projection of the respective planarization enhancing block on a base substrate substantially covers (e.g., covers at least 80%, covers at least 85%, covers at least 90%, covers at least 95%, covers at least 99%, or completely covers) an orthographic projection of a respective subpixel aperture of the plurality of subpixel apertures on the base substrate.

In one particular example, an orthographic projection of the first planarization enhancing block PEB1 on a base substrate completely covers an orthographic projection of the first subpixel aperture SA1 on the base substrate. The orthographic projection of the first planarization enhancing block PEB1 on the base substrate partially overlaps with an orthographic projection of the first main anode part MAP1 on the base substrate. Specifically, the first main anode part MAP1 includes a first edge portion EP1 on a first side S1 of the first subpixel aperture SA1, a second edge portion EP2 on a second side S2 of the first subpixel aperture SA1, a third edge portion EP3 on a third side S3 of the first subpixel aperture SA1, and a fourth edge portion EP4 on a fourth side S4 of the first subpixel aperture SA1. The first side S1 and the second side S2 are opposite to each other. The third side S3 and the fourth side S4 are opposite to each other. Optionally, the orthographic projection of the first planarization enhancing block PEB1 on the base substrate is non-overlapping with an orthographic projection of the first edge portion EP1 on the base substrate, is non-overlapping with an orthographic projection of the second edge portion EP2 on the base substrate, is non-overlapping with an orthographic projection of the third edge portion BP3 on the base substrate, and is non-overlapping with an orthographic projection of the fourth edge portion EP4 on the base substrate. Optionally, the first edge portion EP1 and the second edge portion EP2 have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the first main anode part MAP1, intersecting the first main anode part MAP1, and substantially parallel to a second direction DR2. Optionally, the third edge portion EP3 and the fourth edge portion EP4 have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the first main anode part MAP1, intersecting the first main anode part MAP1, and substantially parallel to a first direction DR1.

In another particular example, an orthographic projection of the second planarization enhancing block PEB2 on a base substrate completely covers an orthographic projection of the second subpixel aperture SA2 on the base substrate. The orthographic projection of the second planarization enhancing block PEB2 on the base substrate completely covers an orthographic projection of the second main anode part MAP2 on the base substrate.

In another particular example, an orthographic projection of the third planarization enhancing block PEB3 on a base substrate completely covers an orthographic projection of the third subpixel aperture SA3 on the base substrate. The orthographic projection of the third planarization enhancing block PEB3 on the base substrate partially overlaps with an orthographic projection of the third main anode part MAP3 on the base substrate. Specifically, the third main anode part MAP3 includes a corner portion CP on a first side SI of the third subpixel aperture SA3 and a main portion MP connected to the corner portion CP. Optionally, the orthographic projection of the third planarization enhancing block PEB3 on the base substrate is non-overlapping with an orthographic projection of the corner portion CP on the base substrate, and completely covers an orthographic projection of the main portion MP on the base substrate. Optionally, the corner portion CP has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the third main anode part MAP3, intersecting the third main anode part MAP3, and substantially parallel to a second direction DR2. Optionally, the main portion MP has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the third main anode part MAP3, intersecting the third main anode part MAP3, and substantially parallel to a second direction DR2.

In another particular example, an orthographic projection of the fourth planarization enhancing block PEB4 on a base substrate completely covers an orthographic projection of the fourth subpixel aperture SA4 on the base substrate. The orthographic projection of the fourth planarization enhancing block PEB4 on the base substrate partially overlaps with an orthographic projection of the fourth main anode part MAP4 on the base substrate. Specifically, the fourth main anode part MAP4 includes a corner portion CP on a first side S1 of the fourth subpixel aperture SA4 and a main portion MP connected to the comer portion CP. Optionally, the orthographic projection of the fourth planarization enhancing block PEB4 on the base substrate is non-overlapping with an orthographic projection of the comer portion CP on the base substrate, and completely covers an orthographic projection of the main portion MP on the base substrate. Optionally, the comer portion CP has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the fourth main anode part MAP4, intersecting the fourth main anode part MAP4, and substantially parallel to a second direction DR2. Optionally, the main portion MP has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the fourth main anode part MAP4, intersecting the fourth main anode part MAP4, and substantially parallel to a second direction DR2.

In some embodiments, the first planarization enhancing block PEB1, the second planarization enhancing block PEB2, the third planarization enhancing block PEB3, and the fourth planarization enhancing block PEB4 are parts of a unitary structure in the third signal line layer. In some embodiments, the first planarization enhancing block PEB1, the second planarization enhancing block PEB2, the third planarization enhancing block PEB3, and the fourth planarization enhancing block PEB4 are parts of an interconnected voltage supply network in the third signal line layer. Optionally, the plurality of planarization enhancing blocks are interconnected by a plurality of bridges.

In some embodiments, the plurality of planarization enhancing blocks in the third signal line layer has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to an individual anode, intersecting the individual anode, and substantially parallel to a second direction DR2.

In some embodiments, the interconnected voltage supply network in the third signal line layer has a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to an individual anode, intersecting the individual anode, and substantially parallel to a second direction DR2.

The inventors of the present disclosure discover that, by having the intricate structure depicted in FIG. 16A to FIG. 16L, the array substrate achieves an even surface of the planarization layer underneath the plurality of anodes AD. As a result, color separation issue can be alleviated.

In the array substrate described in the present disclosure, the array substrate includes a base substrate, a signal line layer closest to an anode, an anode layer on a side of the signal line layer closest to the anode; a pixel definition layer; and a plurality of subpixel apertures extending through the pixel definition layer. The anode layer includes a plurality of anodes. The third signal line layer includes a plurality of signal lines. In some embodiments, an orthographic projection of a portion of a respective anode of the plurality of anodes in a respective subpixel aperture of the plurality of subpixel apertures on a base substrate at least partially overlaps with an orthographic projection of the third signal line layer on the base substrate, forming one or more overlapping areas. In some embodiments, the one or more overlapping areas have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the respective anode and intersecting the respective anode. Optionally, the one or more overlapping areas have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the respective anode, intersecting the respective anode, and substantially parallel to a second direction.

In some embodiments, the array substrate includes a base substrate, a signal line layer closest to an anode, an anode layer on a side of the signal line layer closest to the anode; a pixel definition layer; and a plurality of subpixel apertures extending through the pixel definition layer. The one or more overlapping areas are at least partially in a region corresponding to the plurality of subpixel apertures, In some embodiments, the one or more overlapping areas in the region corresponding to the plurality of subpixel apertures have a substantial (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to a plane perpendicular to the respective anode, intersecting the respective anode, and substantially parallel to a second direction.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating an array substrate. In some embodiments, the method includes forming a signal line layer closest to an anode on a base substrate; forming an anode layer on a side of the signal line layer closest to the anode away from the base substrate; forming a pixel definition layer; and forming a plurality of subpixel apertures extending through the pixel definition layer. Optionally, forming the anode layer includes forming a plurality of anodes. Optionally, forming the signal line layer closest to the anode comprises forming a plurality of signal lines. Optionally, an orthographic projection of a portion of a respective anode of the plurality of anodes in a respective subpixel aperture of the plurality of subpixel apertures on a base substrate at least partially overlaps with an orthographic projection of the signal line layer closest to the anode on the base substrate, forming one or more overlapping areas. Optionally, the one or more overlapping areas have a substantial mirror symmetry with respect to a plane perpendicular to the respective anode and intersecting the respective anode.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising:
a base substrate;
a signal line layer closest to an anode on the base substrate;
an anode layer on a side of the signal line layer closest to the anode away from the base substrate;
a pixel definition layer; and
a plurality of subpixel apertures extending through the pixel definition layer;
wherein the anode layer comprises a plurality of anodes;
the signal line layer closest to the anode comprises a plurality of signal lines;
an orthographic projection of a portion of a respective anode of the plurality of anodes in a respective subpixel aperture of the plurality of subpixel apertures on the base substrate at least partially overlaps with an orthographic projection of the signal line layer closest to the anode on the base substrate, forming one or more overlapping areas; and
the one or more overlapping areas have a substantial mirror symmetry with respect to a plane perpendicular to the respective anode and intersecting the respective anode.

2. The array substrate of claim 1, wherein the signal line layer closest to the anode comprises a plurality of planarization enhancing blocks; and
an orthographic projection of a respective planarization enhancing block of the plurality of planarization enhancing blocks on the base substrate substantially covers an orthographic projection of at least a main anode part of a respective anode of the plurality of anodes on the base substrate.

3. The array substrate of claim 2, wherein the orthographic projection of the main anode part on the base substrate substantially overlaps with an orthographic projection of a central region of the respective planarization enhancing block on the base substrate; and
an orthographic projection of a peripheral region of the respective planarization enhancing block on the base substrate surrounds the orthographic projection of the main anode part on the base substrate.

4. The array substrate of claim 2, wherein the plurality of planarization enhancing blocks are parts of a unitary structure.

5. The array substrate of claim 1, wherein an orthographic projection of at least a main anode part of a respective anode of the plurality of anodes on the base substrate is at least partially surrounded by an orthographic projection of portions of the signal line layer closest to the anode on the base substrate in a substantially symmetrical manner.

6. The array substrate of claim 1, wherein the anode layer comprises a first respective anode;
the signal line layer closest to the anode comprises multiple signal lines;
an orthographic projection of the first respective anode on the base substrate at least partially overlaps with each of orthographic projections of the multiple signal lines on the base substrate; and
the multiple signal lines are substantially evenly distributed along a first direction with respect to a first main anode part of the first respective anode.

7. The array substrate of claim 6, wherein portions of the multiple signal lines, in a region crossing over the first respective anode, have a substantial mirror symmetry with respect to a plane perpendicular to the first respective anode, intersecting the first respective anode, and substantially parallel to a second direction.

8. The array substrate of claim 6, wherein the multiple signal lines comprise a first signal line, a second signal line, and a third signal line;
the first signal line and the third signal line are two adjacent data lines of a plurality of data lines configured to provide data signals to two adjacent columns of subpixels, respectively; and
the second signal line is a low voltage signal line configured to provide a low voltage signal to a cathode of a light emitting element.

9. The array substrate of claim 1, wherein the anode layer comprises a third respective anode;
the signal line layer closest to the anode comprises a fourth signal line;
an orthographic projection of the third respective anode on the base substrate at least partially overlaps with an orthographic projection of the fourth signal line on the base substrate; and
a portion of the fourth signal line, in a region crossing over the third respective anode, have a substantial mirror symmetry with respect to a plane perpendicular to the third respective anode, intersecting the third respective anode, and substantially parallel to a second direction.

10. The array substrate of claim 9, wherein the fourth signal line is a voltage supply line configured to provide a voltage supply signal to a pixel driving circuit.

11. The array substrate of claim 1, wherein the anode layer comprises a plurality of anodes;
the signal line layer closest to the anode comprises a signal line;
an orthographic projection of a respective anode of the plurality of anodes on the base substrate at least partially overlaps with an orthographic projection of the signal line on the base substrate;
a portion of the signal line, in a region crossing over the respective anode, have a substantial mirror symmetry with respect to a plane perpendicular to the respective anode, intersecting the respective anode, and substantially parallel to a second direction;
the signal line layer closest to the anode further comprises a first portion and a second portion;
an orthographic projection of the first portion on the base substrate is on a first side of the orthographic projection of at least a main anode part of an individual anode on the base substrate;
an orthographic projection of a second portion on the base substrate is on a second side of the orthographic projection of at least the main anode part of the individual anode on the base substrate, the first side being opposite to the second side; and
the orthographic projection of the first portion on the base substrate and the orthographic projection of the second portion on the base substrate have a substantial mirror symmetry with respect to a plane perpendicular to the individual anode, intersecting the individual anode, and substantially parallel to the second direction.

12. The array substrate of claim 1, wherein the anode layer comprises a plurality of anodes;
the signal line layer closest to the anode comprises a first signal line, a second signal line, a third signal line, and a fourth signal line;
an orthographic projection of at least a main anode part of a respective anode of the plurality of anodes on the base substrate at least partially overlaps with an orthographic projection of the first signal line on the base substrate, at least partially overlaps with an orthographic projection of the second signal line on the base substrate, at least partially overlaps with an orthographic projection of the third signal line on the base substrate, and at least partially overlaps with an orthographic projection of the fourth signal line on the base substrate;
the first signal line is on a first side of a central point of the main anode part of the respective anode, the second signal line is on a second side of the central point of the main anode part of the respective anode, the third signal line is on a third side of the central point of the main anode part of the respective anode, and the fourth signal line is on a fourth side of the central point of the main anode part of the respective anode;
the first side and the second side are opposite to each other;
the third side and the fourth side are opposite to each other;
the orthographic projection of the first signal line on the base substrate and the orthographic projection of the second signal line on the base substrate have a substantial mirror symmetry with respect to a plane intersecting the central point of the main anode part of the respective anode, perpendicular to the main anode part of the respective anode, and substantially parallel to a second direction; and
the orthographic projection of the third signal line on the base substrate and the orthographic projection of the fourth signal line on the base substrate have a substantial mirror symmetry with respect to a plane intersecting the central point of the main anode part of the respective anode, perpendicular to the main anode part of the respective anode, and substantially parallel to a first direction.

13. The array substrate of claim 12, wherein the first signal line, the second signal line, the third signal line, and the fourth signal line are signal lines in an interconnected voltage supply network in the signal line layer closest to the anode.

14. The array substrate of claim 13, wherein the interconnected voltage supply network in the third signal line layer has a substantial mirror symmetry with respect to a plane perpendicular to an individual anode, intersecting the individual anode, and substantially parallel to the second direction;
wherein the array substrate further comprises:
an encapsulating layer on a side of the third signal line layer away from the base substrate; and
a black matric and a color filter on a side of the encapsulating layer away from the third signal line layer.

15. The array substrate of claim 1, wherein the signal line layer closest to the anode comprises a plurality of planarization enhancing blocks; and
an orthographic projection of a respective planarization enhancing block of the plurality of planarization enhancing blocks on the base substrate substantially covers an orthographic projection of a respective subpixel aperture of the plurality of subpixel apertures on the base substrate.

16. The array substrate of claim 15, wherein an orthographic projection of the respective planarization enhancing block on the base substrate substantially covers an orthographic projection of at least a main anode part of the respective anode on the base substrate.

17. The array substrate of claim 15, wherein the anode layer comprises a first respective anode;
the plurality of planarization enhancing blocks comprise a first planarization enhancing block;
the plurality of subpixel apertures comprise a first subpixel aperture;
a first main anode part of the first respective anode is in contact with organic materials through the first subpixel aperture;
an orthographic projection of the first planarization enhancing block on the base substrate completely covers an orthographic projection of the first subpixel aperture on the base substrate, and partially overlaps with an orthographic projection of a first main anode part of the first respective anode on the base substrate;
the first main anode part comprises a first edge portion on a first side of the first subpixel aperture, a second edge portion on a second side of the first subpixel aperture, a third edge portion on a third side of the first subpixel aperture, and a fourth edge portion on a fourth side of the first subpixel aperture;
the first side and the second side are opposite to each other;
the third side and the fourth side are opposite to each other;
the orthographic projection of the first planarization enhancing block on the base substrate is non-overlapping with an orthographic projection of the first edge portion on the base substrate, is non-overlapping with an orthographic projection of the second edge portion on the base substrate, is non-overlapping with an orthographic projection of the third edge portion on the base substrate, and is non-overlapping with an orthographic projection of the fourth edge portion on the base substrate;
the first edge portion and the second edge portion have a substantial mirror symmetry with respect to a plane perpendicular to the first main anode part, intersecting the first main anode part, and substantially parallel to a second direction; and
the third edge portion and the fourth edge portion have a substantial mirror symmetry with respect to a plane perpendicular to the first main anode part, intersecting the first main anode part, and substantially parallel to a first direction.

18. The array substrate of claim 15, wherein the anode layer further comprises a second respective anode and a third respective anode;
the plurality of planarization enhancing blocks further comprise a second planarization enhancing block and a third planarization enhancing block;
the plurality of subpixel apertures further comprise a second subpixel aperture and a third subpixel aperture;
a second main anode part of the second respective anode is in contact with organic materials through the second subpixel aperture;
an orthographic projection of the second planarization enhancing block on the base substrate completely covers an orthographic projection of the second subpixel aperture on the base substrate, and completely covers an orthographic projection of the second main anode part on the base substrate;
a third main anode part of the third respective anode is in contact with organic materials through the third subpixel aperture;
an orthographic projection of the third planarization enhancing block on the base substrate completely covers an orthographic projection of the third subpixel aperture on the base substrate, and partially overlaps with an orthographic projection of the third main anode part on the base substrate;
the third main anode part comprises a corner portion on a first side of the third subpixel aperture and a main portion connected to the corner portion;
the orthographic projection of the third planarization enhancing block on the base substrate is non-overlapping with an orthographic projection of the corner portion on the base substrate, and completely covers an orthographic projection of the main portion on the base substrate;
the corner portion has a substantial mirror symmetry with respect to a plane perpendicular to the third main anode part, intersecting the third main anode part, and substantially parallel to a second direction; and
the main portion has a substantial mirror symmetry with respect to a plane perpendicular to the third main anode part, intersecting the third main anode part, and substantially parallel to the second direction.

19. A display apparatus, comprising the array substrate of claim 1, and one or more integrated circuits connected to the array substrate.

20. An array substrate, comprising:
a base substrate;
a first signal line layer on the base substrate;
a first planarization layer on a side of the first signal line layer away from the base substrate;
a second signal line layer on a side of the first planarization layer away from the first signal line layer;
a second planarization layer on a side of the second signal line layer away from the first planarization layer;
a third signal line layer on a side of the second planarization layer away from the second signal line layer;
an anode layer on a side of the third signal line layer away from the base substrate;
a pixel definition layer; and
a plurality of subpixel apertures extending through the pixel definition layer;
wherein the third signal line layer is a signal line layer closest to the anode layer; and
wherein the anode layer comprises a plurality of anodes;
the second signal line layer comprises a plurality of a first voltage supply line extends along a first direction;
the third signal line layer comprises a plurality of a first voltage supply line extends along a second direction;
the third signal line layer comprises a plurality of signal lines;
an orthographic projection of a portion of a respective anode of the plurality of anodes in a respective subpixel aperture of the plurality of subpixel apertures on the base substrate at least partially overlaps with an orthographic projection of the signal line layer closest to the anode on the base substrate, forming one or more overlapping areas; and
the one or more overlapping areas have a substantial mirror symmetry with respect to a plane perpendicular to the respective anode and intersecting the respective anode.
